(19) United States
(12) Patent Application Publication
(10) Pub. No.: US 2010/0176380 A1
(43) Pub. Date: Jul. 15, 2010

(54) ORGANIC PHOTOELECTRIC DEVICE AND MATERIAL USED THEREIN

(76) Inventors: Ho Kuk Jung, Incheon (KR); Eui Su Kang, Gyeonggi-do (KR); Myeong Soon Kang, Gyeonggi-do (KR); Jin Seong Park, Gyeonggi-do (KR); Eun Sun Yu, Gyeonggi-do (KR); Dal Ho Huh, Gyeonggi-do (KR); Mi Young Chae, Gyeonggi-do (KR); Jang Hyuk Kwon, Gyeonggi-do (KR); Jin Jang, Seoul (KR); Tae Jin Park, Seoul (KR); Woo Sik Jeon, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/451,746

(22) PCT Filed: May 30, 2008
(86) PCT No.: PCT/KR2008/003076

§ 371 Date: Mar. 15, 2010

(30) Foreign Application Priority Data
May 30, 2007 (KR) 10-2007-0052635
May 30, 2007 (KR) 10-2007-0052637
Jun. 27, 2007 (KR) 10-2007-0063876

(51) Int. Cl. H01L 51/54

(52) U.S. Cl. 257/40; 257/E51.041

(57) ABSTRACT

The present invention relates to an organic photoelectric device and a material used therein. The organic photoelectric device includes a substrate, an anode disposed on the substrate, a hole transport layer (HTL) disposed on the anode, an emission layer disposed on the hole transport layer (HTL), and a cathode disposed on the emission layer. The emission layer is characterized in that it includes a host and a phosphorescent dopant, and the host has a difference between the reduction potential or oxidation potential of the host and the reduction potential or oxidation potential of the phosphorescent dopant of less than 0.5 eV. The organic photoelectric device according to the present invention is capable of accomplishing higher efficiency and a lower driving voltage than those of the conventional organic photoelectric device, and has a simplified structure resulting in saving of manufacturing cost.

### TECHNICAL FIELD

The present invention relates to an organic photoelectric device and a material used therein. More particularly, the present invention relates to an organic photoelectric device having high efficiency and a low driving voltage and that can be made in a simplified structure resulting in saving of manufacturing cost and a material used therein.

### BACKGROUND ART

An organic photoelectric device is a device requiring a charge exchange between an electrode and an organic material by using a hole or an electron.

As examples, the organic photoelectric device includes an organic light emitting diode (OLED), an organic solar cell, an organic photo-conductor drum, an organic transistor, an organic memory device, etc., and it requires a hole injecting or transporting material, an electron injecting or transporting material, or a light emitting material.

Although the organic light emitting diode is mainly described in the following description, the hole injecting or transporting material, the electron injecting or transporting material, and the light emitting material react in similar principles in the organic photoelectric devices.

The organic light emitting diode is a device that transforms electrical energy into light by applying a charge to an organic material and has a structure in which a functional organic material layer is inserted between an anode and a cathode.

It was firstly observed in the 1960's [U.S. Pat. No. 3,172,862 1965, J. Chem. Phys. 38 2042 1963], and C. W. Tang of Eastman Kodak disclosed a bilayer organic light emitting diode that shows high-luminance light emission at a low voltage [Appl. Phys. Lett. 51, 913 1987]. Recent organic light emitting diodes have been remarkably improved in view of color, luminous efficiency, and device stability. These improvements provide the motive to draw attention to the same as the next generation flat panel display.

A phosphorescent organic light emitting diode can theoretically be five times as efficient as a fluorescent organic light emitting diode (theoretical efficiency 100%), so it is anticipated to be widely utilized. A phosphorescent organic light emitting diode can show a higher light-emitting characteristic and efficiency characteristic than those of a fluorescent organic light emitting diode by doping 5 to 10 mol % of a phosphorescent dopant material in a solid fluorescent host. In addition, the external quantum efficiency can overcome the limits of the same of the fluorescent material.

FIG. 1 is a schematic cross-sectional view of a conventional phosphorescent organic light emitting diode (OLED). Referring to FIG. 1, the conventional organic light emitting diode is sequentially formed of an anode 120 disposed on a substrate 110, a hole transport layer (HTL) 130 disposed on the anode 120 and transporting holes injected from the anode 120 to an emission layer (EML) 140 disposed on the hole transport layer (HTL) 130, a hole blocking layer (HBL) 150 disposed on the emission layer and preventing the holes from reaching a cathode 170, an electron transport layer (ETL) 160 disposed thereon and transporting electrons injected from the cathode to the emission layer, and a cathode 170 disposed on the electron transport layer. The multi-layer structure has problems in that the manufacturing cost is high due to a high number of processes, and in that the number of organic materials and interfaces between the organic materials is high such that the driving voltage is increased.

FIG. 2 is an energy diagram of the conventional phosphorescent organic light emitting diode (OLED). Referring to FIG. 2, the emission layer structure of the phosphorescent organic light emitting diode includes a host organic material having a large band gap in the emission layer in order to capture a triplet excited state in the emission layer. The light emitting process includes the steps of absorbing energy in a singlet excited state (A) of the fluorescent host, transferring the triplet excited state (B) of a phosphorescent dopant to lose energy due to the light emitting, and returning to the ground state.

The fluorescent host used in the conventional phosphorescent organic light emitting diode has an excessively large energy difference between the singlet excited state (A) and the triplet excited state (C) to transfer the energy to the triplet excited state (B) of the phosphorescent dopant, thereby causing a problem that the luminous efficiency is deteriorated.

In addition, the electron transport layer transporting the electrons to the emission layer should be included since the electrons are difficult to inject due to a high energy barrier and a low electron mobility of the fluorescent host, and the hole blocking layer should be included in order to prevent holes from reaching the cathode. This causes problems in that the manufacturing cost is increased, it is difficult to accomplish slimming of the device, the structure of the organic light emitting diode becomes more complicated due to the electron transport layer and the hole blocking layer, and the luminous efficiency is decreased due to a large energy difference between the singlet excited state (A) of the fluorescent host and the triplet excited state (C).

On the other hand, methods of expressing white light that have recently been actively researched include a three-color separate coating method using each of R (red), G (green), and B (blue) emission layers, a method including forming a white emission layer and using a color filter, and a method including forming a blue emission layer and using a color-changing material to express green and red.

FIG. 3 is a schematic cross-sectional view of a conventional white organic light emitting diode (OLED) according to the three-color separate coating method.

Referring to FIG. 3, the conventional organic light emitting diode is sequentially formed of a substrate 110, an anode 120 disposed on the substrate, a hole transport layer (HTL) 130 disposed on the anode 120 and transporting holes to an emission layer 140, a red emission layer (R EML) 141 disposed on the hole transport layer 130, a green emission layer (G EML) 142 disposed on the red emission layer 141, a blue emission layer (B EML) 143 disposed on the green emission layer 142, a hole blocking layer (HBL) 150 disposed on the blue emission layer 143, and an electron transport layer (ETL) 160 and a cathode 170 disposed on the hole blocking layer 150.

The organic light emitting diode (OLED) fabricated by the three-color separate coating method is a method of forming R, G, and B organic layers, as shown in FIG. 3, including evaporating a selected low-molecular organic material on only a desired pixel using a metal shadow mask, but there is a limit in increasing the display size due to manufacturing precision and unevenness of evaporation layer caused by the mask thickness.

The panel fabricated by the three-color separate coating method can improve efficiency and decrease power consumption when a white light emitting pixel is added, so research thereon is actively progressing. In addition, the method using the white emission layer and color filter and the color-changing method are slowly gaining popularity. Particularly, a method of forming a white emission layer and using a color filter has merits including enlargement and high resolution due to the simple organic layer, and of applying the manufacturing apparatus or material for a TFT in the conventional liquid crystal industry developing methods.

However, the overall pass efficiency of the color filter is low at ⅓ for the white material, so a highly efficient material is required. In addition, the white material has an insufficient life-span, so commercialization is imminent.

### [Disclosure]

In order to solve the problems, the purpose of the present invention is to provide an organic photoelectric device that has high efficiency and a low driving voltage, that can be made in a simplified thin structure, and that decreases manufacturing cost.

Another purpose of the present invention is to provide an organic photoelectric device showing high efficiency and a low driving voltage even though an emission layer includes a small amount of a phosphorescent dopant doped on a host.

Another purpose of the present invention is to provide a host material having new efficient energy transfer and electron transport characteristics and that is capable of providing a low molecular emission layer structure of an organic photoelectric device.

The embodiments of the present invention are not limited to the above technical purposes, and a person of ordinary skill in the art can understand other technical purposes.

In order to obtain the above purposes, one embodiment of the present invention provides an organic photoelectric device including a substrate, an anode disposed on the substrate, a hole transport layer (HTL) disposed on the anode, an emission layer disposed on the hole transport layer (HTL), and a cathode disposed on the emission layer. The emission layer includes a host and a phosphorescent dopant, and a difference between a reduction potential or an oxidation potential of the host and a reduction potential or an oxidation potential of the phosphorescent dopant is less than 0.5 eV.

The host has an energy difference between a singlet excited state and a triplet excited state of 0.3 eV or less, and preferably 0.2 eV or less.

The host is an organic metal complex compound represented by the following Formula 1 or 2.

ML [Chemical Formula 1]

ML₁L₂ [Chemical Formula 2]

In the above formulae, M is selected from the group consisting of Li, Na, Mg, K, Ca, Al, Be, Zn, Pt, Ni, Pd, and Mn, and L, L₁, and L₂ are independently a ligand. L₁ and L₂ are the same or different.

The host is represented by the following Formula 3.

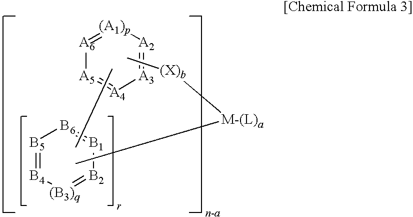

In the above formula:

A₁ to A₆ are independently CR₁R₂ (where R₁ and R₂ are independently selected from the group consisting of hydrogen, a halogen, a nitrile, a cyano, a nitro, an amide, a carbonyl, an ester, a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₁ and R₂ of A₁ to A₆ is linked to at least one non-adjacent R₁ and R₂ of A₁ to A₆ to form a fused ring);

B₁ to B₆ are independently CR₃R₄ or NR₅ (where R₃, R₄, and R₅ are independently hydrogen, a halogen, a nitrile, a cyano, a nitro, an amide, a carbonyl, an ester; a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₃, R₄, and R₅ of B₁ to B₆ is linked to at least one non-adjacent R₃, R₄, and R₅ of B₁ to B₆ to form a fused ring); or

at least one of R₁ and R₂ of A₁ to A₆ is linked to at least one of R₃, R₄, and R₅ of B₁ to B₆ to form a fused ring;

p, q, and r are independently an integer of 0 or 1;

L is selected from the group consisting of OR₆ and OSiR₇R₈ (where R₆, R₇, and R₈ are independently an aryl, an alkyl-substituted aryl, an arylamine, a cycloalkyl, and a heterocycle);

M is selected from the group consisting of Li, Na, Mg, K, Ca, Al, Be, Zn, Pt, Ni, Pd, and Mn;

X is oxygen or sulfur;

n is a metal valence; and a and b are independently 0 or 1.

The phosphorescent dopant is included in an amount of 0.5 to 20 wt % based on the total amount of light emitting materials (sum of a host and a phosphorescent dopant).

The emission layer is formed by simultaneously depositing or coating the host and phosphorescent dopant.

The organic photoelectric device may further include a hole blocking layer or an electron transport layer (ETL) disposed on the emission layer.

The organic photoelectric device may further include a hole blocking layer disposed on the emission layer, and an electron transport layer (ETL) disposed on the hole blocking layer.

Hereinafter, other embodiments of the present invention will be described in detail.

Exemplary embodiments of the present invention will hereinafter be described in detail with reference to the accompanying drawings. However, these embodiments are only exemplary, and the present invention is not limited thereto but rather is defined by scope of the appended claims.

FIG. 4 is a schematic cross-sectional view of a phosphorescent organic light emitting diode (OLED) according to one embodiment of the present invention, and FIG. 5 shows a light emitting mechanism of the phosphorescent organic light emitting diode (OLED) shown in FIG. 4.

Referring to FIGS. 4 and 5, the organic light emitting diode according to the present invention is formed by sequentially disposing a substrate 210, an anode 220, a hole transport layer 230, an emission layer 240, and a cathode 250.

Firstly, the anode 220 is disposed on the substrate 210.

The substrate 210 is preferably a glass substrate or a transparent plastic substrate having excellent general transparence, face smoothness, handling ease, and water repellency. The thickness of the substrate is preferable between 0.3 and 1.1 mm.

Preferably, the anode 220 includes a material having a high work function that is sufficient to facilitate the hole injection into a hole transport layer (HTL). The anode material may include: a metal such as nickel, platinum, vanadium, chromium, copper, zinc, iridium, gold, or alloys thereof; a metal oxide such as zinc oxide, indium oxide, indium tin oxide (ITO), indium zinc oxide (IZO); a metal and an oxide such as ZnO and Al or SnO₂ and Sb; a conductive polymer such as poly(3-methylthiophene), poly[3,4-(ethylene-1,2-dioxy)thiophene] (polyethylenedioxythiophene: PEDT), polypyrrol, and polyaniline, but it is not limited thereto. The anode is preferably a transparent electrode of ITO (indium tin oxide).

Preferably, after cleaning the substrate formed with the anode 220, UV ozone treatment is carried out. The cleaning method uses an organic solvent such as isopropanol (IPA), acetone, and so on.

A hole transport layer (HTL) 230 is disposed on the surface of the anode 220. A material for forming the hole transport layer 230 is not limited, but may include at least one selected from the group consisting of 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine, 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′diamine (TPD), N,N′-di(naphthalene-1-il)-N,N′-diphenyl benzidine (α-NPD), N,N′-diphenyl-N,N′-bis(1-naphthyl)-(1,1′-biphenyl)-4,4′-diamine (NPB), IDE320 (manufactured by Idemitu), poly(9,9-dioctylfluorene-co-N-(4-butylphenyl)diphenylamine) (TFB), and poly(9,9-dioctylfluorene-co-bis-N,N-phenyl-1,4-phenylenediamine (PFB).

Preferably, the hole transport layer 230 has a thickness ranging from 5 nm to 200 nm. When the thickness of the hole transport layer (HTL) 230 is less than 5 nm, the hole transporting characteristic is deteriorated; on the other hand, when it is more than 200 nm, it is not preferable since the driving voltage is increased.

An emission layer 240 is disposed on the surface of the hole transport layer (HTL) 230. The emission layer 240 of the organic light emitting diode according to the present invention is formed by simultaneously depositing or coating a host organic material and a phosphorescent dopant.

The host material for forming the emission layer 240 is an organic metal complex compound having a difference between the reduction potential or oxidation potential of the host and the reduction potential or oxidation potential of the phosphorescent dopant of less than 0.5 eV, and hereinafter it will be described in detail.

Examples of the phosphorescent dopant include at least one selected from the group consisting of Ir, Pt, Tb, Eu, Os, Ti, Zr, Hf, and Tm, and more specifically they may include bisthienyl pyridine acetylacetonate iridium, bis(1-acetylacetonate, bis(benzothienyl pyridine)acetylacetonate iridium, bis(2-phenylbenzothiazole)acetylacetonate iridium, tris(2-phenylpyridine)iridium (Ir(ppy)₃), tris(4-biphenylpyridine)iridium, tris(phenylpyridine)iridium, tris(1-phenylisoquinoline)iridium (Ir(piq)₃), bis(2-phenylquinoline)iridium acetylacetonate (Ir(phq)₂acac) and so on, but are not limited thereto.

The deposition may be performed by a method such as evaporation, sputtering, plasma plating, and ion plating, and the coating method may include spin coating, dipping, and flow coating.

Preferably, the emission layer 240 has a thickness ranging from 10 nm to 500 nm, and more preferably it ranges from 30 nm to 50 nm. When the thickness of the emission layer 240 is less than 10 nm, it is not preferable since the leakage current is increased to decrease the efficiency and the life-span; when it is more than 500 nm, the driving voltage is significantly increased.

Preferably, the cathode 250 has a low work function in order to facilitate the electron injection. Specific examples of the cathode material may include a metal such as magnesium, calcium, sodium, potassium, titanium, indium, yttrium, lithium, gadolinium, aluminum, silver, tin, lead, cesium, barium, and so on, or an alloy thereof, but they are not limited thereto. It is possible to provide an electron injection layer (EIL)/cathode having a multi-layered structure such as LiF/Al, LiO₂/Al, LiF/Ca, LiF/Al, BaF₂/Ca, CsF/Al, Cs₂CO₃/Al, and so on. The cathode preferably uses a metal electrode material such as aluminum.

Preferably, the thickness of the cathode 250 ranges from 50 to 300 nm.

As shown in FIG. 5, when the voltage is applied between two electrodes 220 and 250, a hole is injected through the anode 220 and an electron is injected through the cathode 250.

In the organic light emitting diode according to the present invention, the electron implanted from the cathode 250 is transferred directly to the emission layer 240.

The hole transferred from the hole transport layer 230 meets with the electron transferred from the cathode 250 on the emission layer 240 to form an exciton through recombination, and electrical energy of the exciton is inverted to light energy. Light of a color corresponding to the energy band gap of the emission layer is emitted.

More specifically, the material of the emission layer 240 emits light by forming an exciton in the emission layer 240 from the injected hole and electron. When only an emission material is used, it causes a problem of changing the color purity and decreasing the luminous efficiency due to intermolecular interaction between excitons. Therefore, it generally uses a host/dopant system.

The host/dopant system progresses as follows: when the hole and the electron excite the host, the dopant absorbs the generated energy, and the light is again emitted.

According to one embodiment of the present invention, the host is an organic material having a difference between the reduction potential or oxidation potential of the host and the reduction potential or the oxidation potential of the phosphorescent dopant of less than 0.5 eV, preferably 0.4 eV or less, and more preferably 0.2 eV or less. When the difference between the reduction potential or oxidation potential of the host and the reduction potential or oxidation potential of the phosphorescent dopant is less than 0.5 eV, it is possible to accomplish more effective energy transporting from the singlet excited state of the host and the triplet excited state of the phosphorescent dopant. However, in the phosphorescent organic light emitting diode (OLED), it is hard to form excitons since the hole transport is generally faster than the electron transport, but according to the present invention, the excitons are easily formed by using a host of an organic material in which the electron transport is fast and the electrons are easily injected.

The host is an organic metal complex compound represented by the following Formula 1 or 2.

ML [Chemical Formula 1]

ML₁L₂ [Chemical Formula 2]

In the above formulae, M is selected from the group consisting of Li, Na, Mg, K, Ca, Al, Be, Zn, Pt, Ni, Pd, and Mn, and L, L₁, and L₂ are independently a ligand. The L₁ and L₂ may be the same or different.

More specifically, the host may be an organic metal complex compound of the following Formula 3.

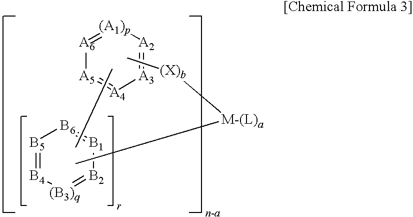

In the above formula:

A₁ to A₆ are independently CR₁R₂ (where R₁ and R₂ are independently selected from the group consisting of hydrogen, a halogen, a nitrile, a cyano, a nitro, an amide, a carbonyl, an ester, a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₁ and R₂ of A₁ to A₆ is linked to at least one non-adjacent R₁ and R₂ of A₁ to A₆ to form a fused ring);

B₁ to B₆ are independently CR₃R₄ or NR₅ (where R₃, R₄, and R₅ are independently hydrogen, a halogen, a nitrile, a cyano, a nitro, an amide, a carbonyl, an ester, a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₃, R₄, and R₅ of B₁ to B₆ are linked to at least one non-adjacent R₃, R₄, and R₅ of B₁ to B₆ to form a fused ring); or

at least one of R₁ and R₂ of A₁ to A₆ are linked to at least one of R₃, R₄, and R₅ of B₁ to B₆ to form a fused ring;

p, q, and r are independently an integer of 0 or 1;

L is selected from the group consisting of OR₆ and OSiR₇R₈ (where R₆, R₇, and R₈ are independently an aryl, an alkyl-substituted aryl, an arylamine, a cycloalkyl, or a heterocycle);

M is selected from the group consisting of Li, Na, Mg, K, Ca, Al, Be, Zn, Pt, Ni, Pd, and Mn;

X is oxygen or sulfur;

n is a metal valence; and a and b are independently 0 or 1.

In the present specification, when specific definition is not provided, an alkyl refers to a C1 to C30 alkyl and preferably a C1 to C20 alkyl, an alkoxy refers to a C1 to C30 alkoxy and preferably a C1 to C20 alkoxy, an aryl refers to a C 6 to C50 aryl and preferably a C6 to C30 aryl, a cycloalkyl refers to a C3 to C50 cycloalkyl and preferably a C4 to C30 cycloalkyl, a halogen refers to F, Cl, Br, or I, and preferably F, an alkenyl refers to a C2 to C30 alkenyl and preferably a C2 to C20 alkenyl, a heterocycle refers to a C2 to C30 heterocycloalkyl or a C2 to C30 heteroaryl, and an amino refers to a C1 to C30 amino.

In the present specification, when specific definition is not provided, the substituted alkyl, alkoxy, aryl, cycloalkyl, alkenyl, arylamine, heteroarylamine, or heterocycle refers to one substituted with at least a substituent selected from the group consisting of an aryl, a heteroaryl, an alkyl, an amino, an alkoxy, a halogen (F, Cl, Br, or I), and a nitro.

Specific examples of the above Formula 3 are represented by the following Formulae 5 to 36.

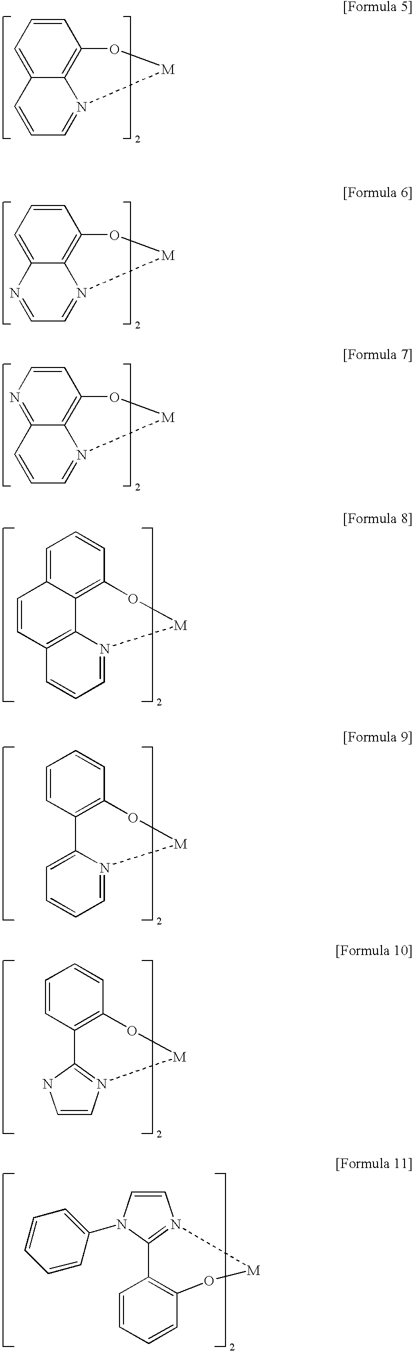

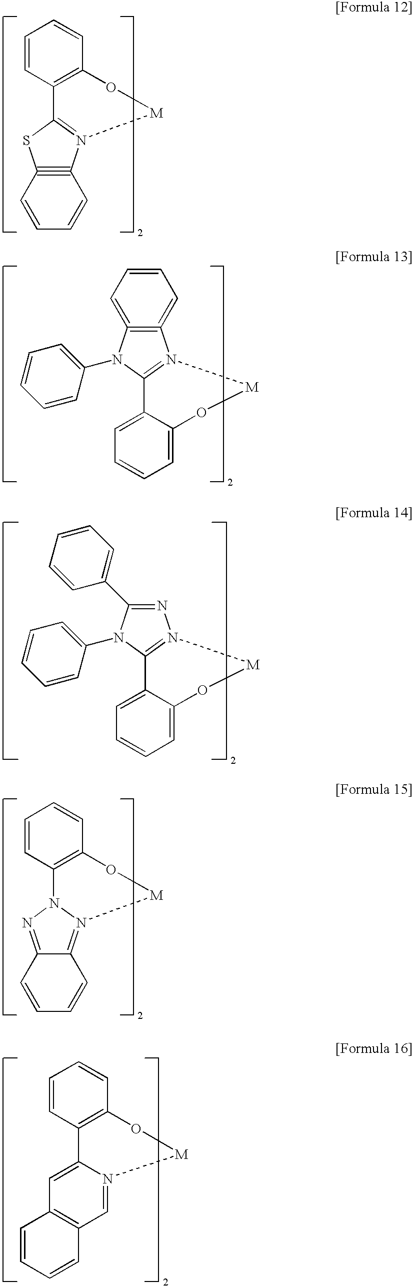

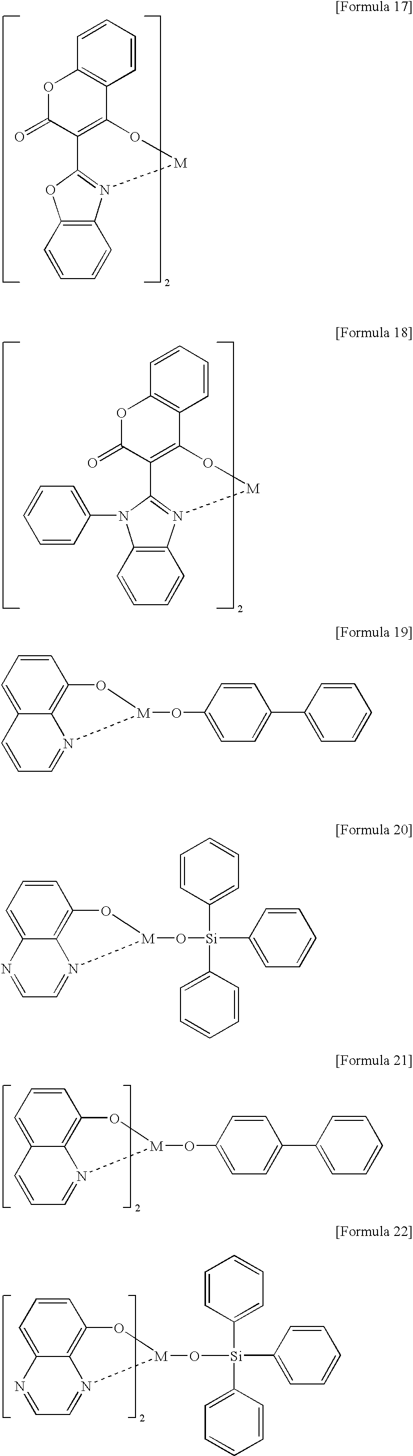

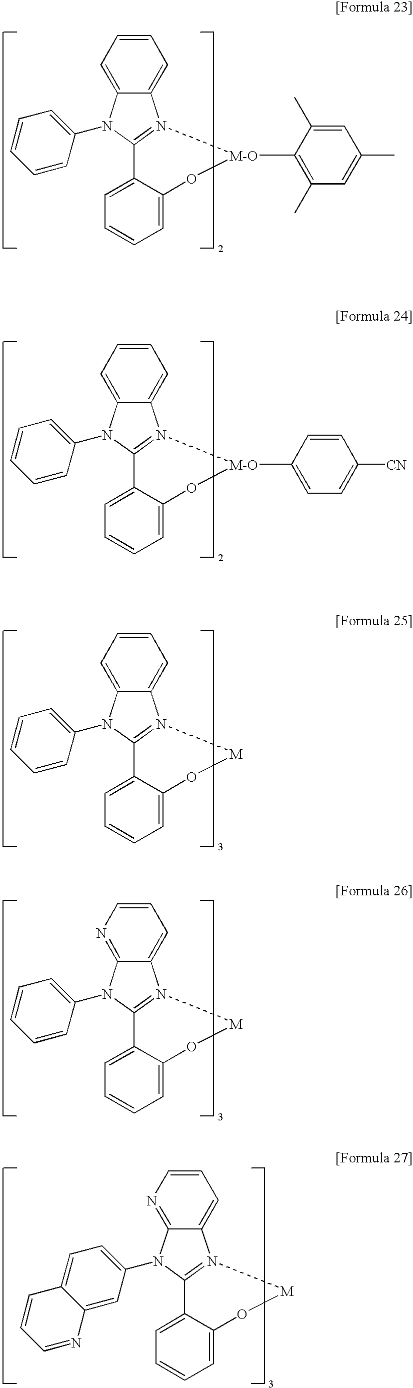

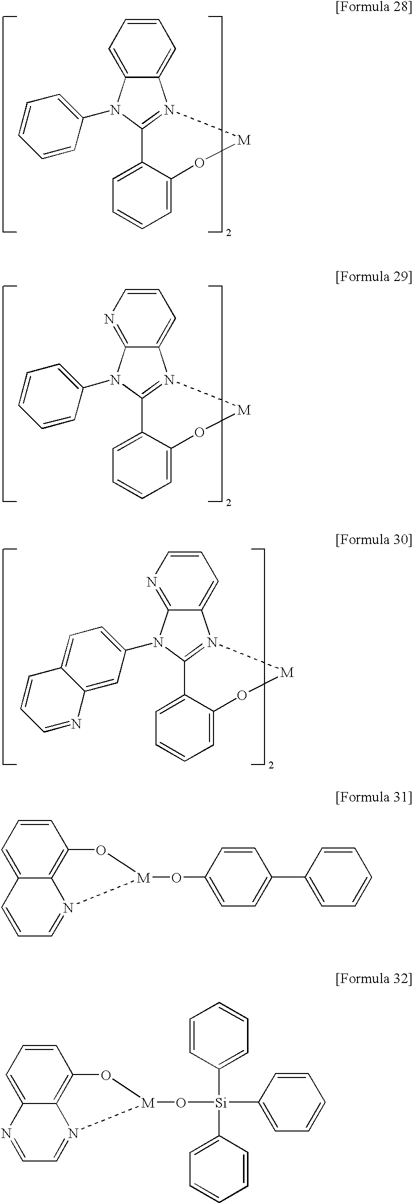

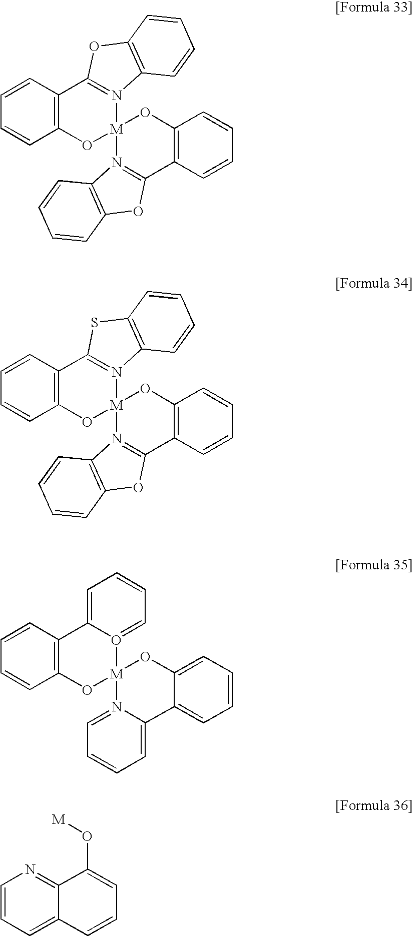

In the above Formulae 5 to 36, M is determined according to valance, and is selected from the group consisting of Li, Na, Mg, K, Ca, Al, Be, Zn, Pt, Ni, Pd, and Mn.

The organic metal complex compound preferably has electron mobility of 10−6 cm²/Vs or more.

It is preferable to choose a metal (M) represented by Formula 1 or 2 and ligands (L, L₁, and L₂) to satisfy the following Equation 1 or 2, so that the difference between the reduction/oxidation potentials of the host and the phosphorescent dopant is less than 0.5 eV.

|H_{R}−D_{R}|<0.5 eV [Equation 1]

|H_{O}−D_{O}|<0.5 eV [Equation 2]

In Equation 1, H_{R} is a reduction potential of the host and D_{R} is a reduction potential of the phosphorescent dopant; in Equation 2, H_{O} is an oxidation potential of the host and D_{O} is an oxidation potential of the phosphorescent dopant.

The host is preferably a fluorescent host having strong fluorescence.

Preferably, the host satisfies the conditions of Equations 1 and 2, and the fluorescent quantum yield of the host is 0.01 or more and more is preferably 0.1 or more.

Preferably, the triplet excited state energy of the host is equal to or higher than the triplet excited state energy of the phosphorescent dopant.

The energy difference between the singlet excited state and the triplet excited state of the host is 0.3 eV or less, and is preferably 0.2 eV or less. If the energy difference between the singlet excited state and the triplet excited state of the host is within 0.3 eV, the host has an excellent charge transport characteristic and the energy barrier for moving the charge is low, so that it is possible to stably provide electrons from the cathode to the emission layer even though there is no electron transport layer.

The emission layer 240 formed with the host and the phosphorescent dopant according to the present invention has electron mobility that is equal to or faster than the hole mobility.

The phosphorescent dopant is added to the emission layer at 0.5 to 20 wt % based on the total weight of the light emitting material (host+dopant), and preferably it ranges from 0.5 to 10 wt %, more preferably it ranges from 0.5 to 5 wt %, and further more preferably it ranges from 0.5 to 3 wt %. When the phosphorescent dopant is added at more than 20 wt %, quenching is performed in the phosphorescent dopant to deteriorate the luminous efficiency. When it is less than 0.5 wt %, it is not preferable since the energy is not transferred from the host to the phosphorescent dopant, and non-radiative annihilation occurs to deteriorate the luminous efficiency and the life-span of the device.

The host according to the present invention has a small energy difference between the reduction potential or the oxidation potential of the host and the reduction potential or the oxidation potential of the phosphorescent dopant to facilitate the energy transfer at a low concentration, so that the doping amount of the phosphorescent dopant is remarkably decreased. Accordingly, it is possible to save the high cost phosphorescent dopant so that the cost of manufacturing the device can be decreased.

When the energy difference between the reduction potential or oxidation potential of the host and the reduction potential or oxidation potential of the phosphorescent dopant is 0.2 eV or less, the amount of phosphorescent dopant is decreased to 1 wt % or less.

Furthermore, referring to FIG. 1, in the conventional phosphorescent organic light emitting diode (OLED), the hole blocking layer 150 is disposed on the emission layer 140 in order to prevent deterioration of the life-span and the efficiency of the device when holes are passing to the cathode 170 through the emission layer 140. On the other hand, in the phosphorescent organic light emitting diode of the present invention shown in FIG. 2, as the area for forming excitons is present on the interface of the hole transport layer 230 and it has high energy of the singlet excited state of the fluorescent host, it is possible to prevent the hole from reaching the cathode 250 even though a separate hole blocking layer is not mounted.

Accordingly, the structure is simplified by the omitting electron transport layer and the hole blocking layer, so that it is possible to accomplish slimming of the device. Although it has no electron transport layer and no hole blocking layer, it is possible to produce the organic light emitting diode having sufficiently low voltage and high efficiency. In order to further increase the luminous efficiency, it may further include an organic thin film of either an electron transport layer or a hole blocking layer. In this case, the thickness of the organic thin film preferably ranges from 10 to 30 nm.

Alternatively, it may include both an electron transport layer and a hole blocking layer. Preferably, the electron transport layer has a thickness ranging from 10 to 30 nm, and the hole blocking layer has a thickness ranging from 5 to 10 nm. If the electron transport layer or the hole blocking layer are disposed within the range, the luminous efficiency of organic light emitting diode is further improved.

Preferably, the host material of the emission layer 240 is coated to provide an electron transport layer and a hole blocking layer. According to characteristics of the host material, the thin layer formed on the surface of the emission layer 240 acts as an electron transport layer and/or a hole blocking layer.

The hole injected from the anode 220 into the hole transport layer 230 is transported into the emission layer 240. In order to solve the deterioration problem of the interface between the anode 220 and the hole transport layer (HTL) 230, it may further include a hole injection layer (HIL) (not shown) between the anode 220 and the hole transport layer (HTL) 230 to improve the interface characteristic with suitable surface energy.

The hole injection layer (HIL) is formed by evaporating or spin-coating copper phthalocyanine (CuPc), m-MTDATA which is a starburst amine, TCTA, or PEDOT:PSS which is a conductive polymer composition, and so on.

When the hole injection layer is formed in this way, the contact resistance between the anode 220 and the emission layer 240 can be decreased and the hole transport capacity of the anode to the emission layer 240 is improved, so that it is possible to improve the driving voltage and the life-span characteristic of the organic light emitting diode overall.

When the thickness of the hole injection layer is less than 5 nm, it is not preferable since it is difficult to carry out the hole injection due to the thin hole injection layer; when the thickness of the hole injection layer (HIL) is more than 100 nm, it is not preferable since the light transmittance is deteriorated or the driving voltage is increased. Accordingly, the hole injection layer can be formed in a thickness ranging from 5 nm to 200 nm, and it preferably ranges from 20 nm to 100 nm.

According to another embodiment of the present invention, a white organic light emitting diode (OLED) is provided by using a blue host and a red dopant or a yellow dopant as an emission layer material. Such white organic light emitting diode is prepared by sequentially disposing an anode 320, a hole transport layer 330, a white emitting layer 340, and a cathode 350 on a substrate 310.

The emission layer 340 is formed by simultaneously depositing or coating a host/dopant association selected from the group consisting of the blue host and red dopant, the blue host and yellow dopant, the blue host and green and red dopants, and the blue host and green and yellow dopants. The host is an organic material having a difference between the reduction potential or oxidation potential of the host and a reduction potential or oxidation potential of the phosphorescent dopant that is less than 0.5 eV, preferably 0.4 eV or less, and more preferably 0.2 eV or less. Accordingly, preferably, it may be an organic metal complex compound represented by the above Formulae 1 to 36.

The white emission layer 340 uses the energy transfer phenomenon transferring from the singlet excited state of the host to the triplet excited state of phosphorescent dopant, and simultaneously, the energy transfer phenomenon transferring from the triplet excited state of the host to the triplet excited state of the phosphorescent dopant, to emit white light.

Referring to FIG. 7, in order to research the emission mechanism of the white emission layer 340, the blue host and red dopant, and the blue host and yellow dopant are used as examples thereof. It absorbs light as the singlet of the blue fluorescent host and loses energy so the blue fluorescent emits light while returning to the ground state of blue fluorescent host, and the singlet of the blue fluorescent host is transferred to the triplet excited state of the red or yellow phosphorescent dopant and at the same time the triplet of the blue fluorescent host is transferred to the triplet excited state of the red or yellow phosphorescent and loses energy, so it emits red or yellow phosphorescent light while returning to the ground state of the phosphorescent dopant. Accordingly, the white light is emitted by mixing the blue fluorescent emission and the red or yellow phosphorescent emission.

According to another embodiment of the present invention, the white emission layer 340 can be formed as a multi-layer emission layer. For example, it can be formed as a multi-layer emission layer selected from the group consisting of a first emission layer including a blue host and a second emission layer including a blue host and red dopant, a first emission layer including a blue host and a second emission layer including a blue host and yellow dopant, a first emission layer including a blue host and a second emission layer including a blue host and green and red dopants, and a first emission layer including a blue host and red dopant and a second emission layer including a blue host and green dopant, but it is not limited thereto.

The white organic light emitting diode having a low molecular single emission layer structure according to the embodiment further improves the energy transfer from the singlet excited state of the host to the triplet excited state of the dopant, compared to those of the conventional white organic light emitting diode, by including an emission layer including a certain association of host/phosphorescent dopant, so it is possible to achieve the high efficiency and low driving voltage and to achieve white light by using single emission layer. As a result, the structure is simplified and the manufacturing cost is reduced due to omitting the hole blocking layer and the electron transport layer.

Although the organic light emitting diode (OLED) is described in detail above, other organic photoelectric devices may be used in the same way.

The organic photoelectric device according to the present invention can be applied to a back-light of thin film transistor (TFT-LCD), a light emitting element of an active-matrix polymer light-emitting display, a lighting device, and so on, but it is not limited thereto.

### DESCRIPTION OF DRAWINGS

FIG. 1 is a schematic cross-sectional view of a conventional phosphorescent organic light emitting diode (OLED).

FIG. 2 is an energy diagram of a phosphorescent organic light emitting diode (OLED).

FIG. 3 is a schematic cross-sectional view of a conventional white organic light emitting diode (OLED).

FIG. 4 is a schematic cross-sectional view of a phosphorescent organic light emitting diode (OLED) according to one embodiment of the present invention.

FIG. 5 shows a light emitting mechanism of the phosphorescent organic light emitting diode (OLED) shown in FIG. 4.

FIG. 6 is a schematic cross-sectional view of a white phosphorescent organic light emitting diode (OLED).

FIG. 7 shows a light emitting mechanism of the white phosphorescent organic light emitting diode (OLED) shown in FIG. 6.

FIGS. 8 and 9 respectively show I-V (current-voltage) and V-L (voltage-luminance) characteristics of the green organic light emitting diodes (OLEDs) according to Example 1 and Comparative Example 1.

FIGS. 10 and 11 show luminous efficiency and electric power efficiency of the green organic light emitting diodes (OLEDs) according to Example 1 and Comparative Example 1.

FIG. 12 shows I-V (current-voltage) characteristics of the red organic light emitting diodes (OLEDs) according to Examples 2-4.

FIG. 13 shows luminous efficiency characteristics of the red organic light emitting diode (OLED) according to Examples 2-4.

FIGS. 14 and 15 respectively show I-V (current-voltage) and V-L (voltage-luminance) characteristics of the red organic light emitting diodes (OLEDs) according to Example 5 and Comparative Example 2.

FIGS. 16 and 17 show luminous efficiency and electric power efficiency of the red organic light emitting diodes (OLEDs) according to Example 5 and Comparative Example 2.

FIGS. 18 and 19 respectively show I-V (current-voltage) and V-L (voltage-luminance) characteristics of the red organic light emitting diodes (OLEDs) according to Examples 8-11.

FIGS. 20 and 21 show luminous efficiency and electric power efficiency of the red organic light emitting diodes (OLEDs) according to Examples 8-11.

FIGS. 22 and 23 respectively show I-V (current-voltage) and V-L (voltage-luminance) characteristics of the red organic light emitting diodes (OLEDs) according to Examples 12-15.

FIGS. 24 and 25 show luminous efficiency and electric power efficiency of the red organic light emitting diodes (OLEDs) according to Examples 12-15.

FIGS. 26 and 27 respectively show I-V (current-voltage) and V-L (voltage-luminance) characteristics of the white organic light emitting diode (OLED) according to Example 16.

FIGS. 28 and 29 show luminous efficiency and electric power efficiency of the white organic light emitting diode (OLED) according to Example 16.

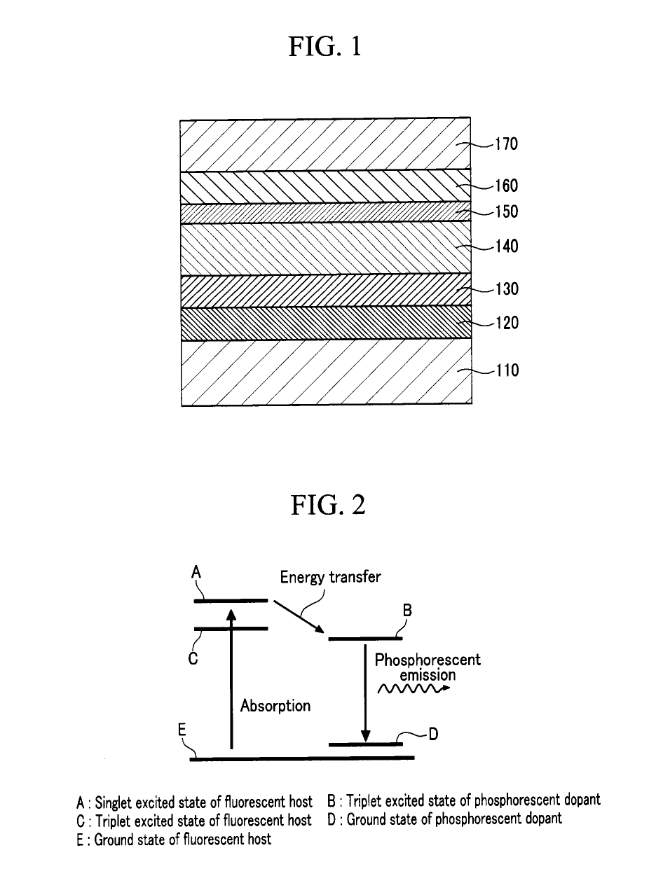

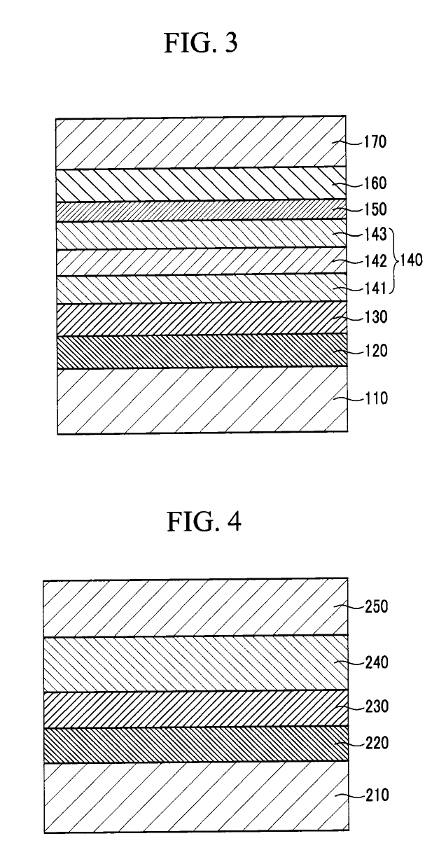

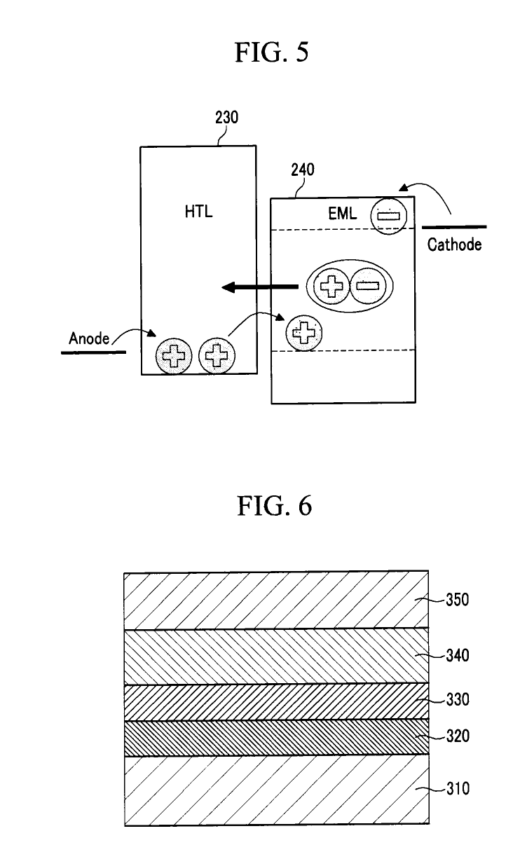

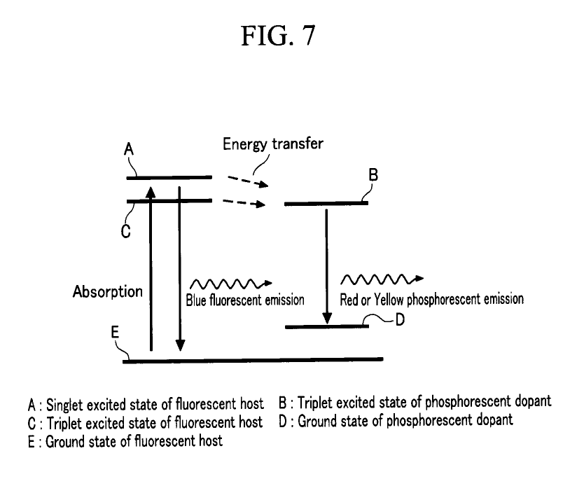

The following examples illustrate the present invention in more detail. However, it is understood that the present invention is not limited by these examples.

### EXAMPLE

### Host and Dopant Material

The emission layer materials for an organic light emitting diode (OLED) include a host and a dopant with the following aspects. The value of HOMO (oxidation potential) and LUMO (reduction potential) was measured through cyclovoltammetry.

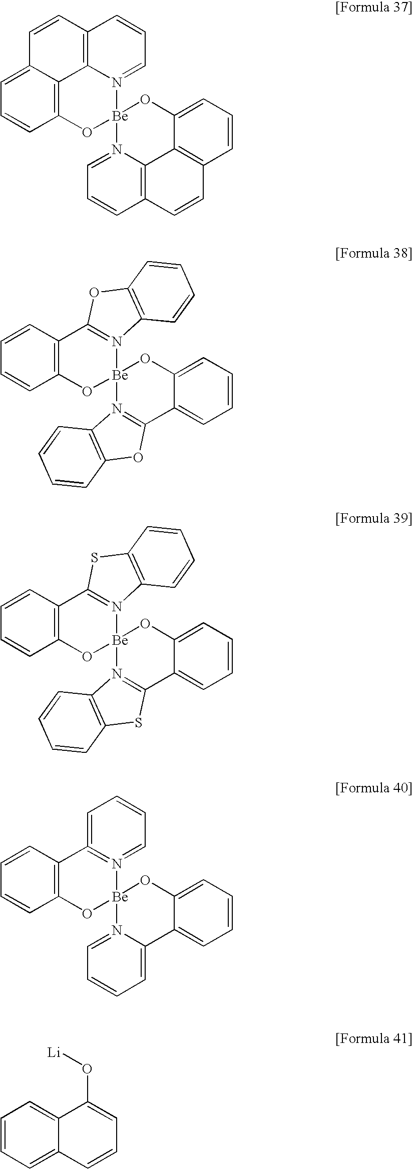

| | | HOMO | LUMO | Triplet | Fluorescent |
|---|---|---|---|---|---|
| | | (eV) | (eV) | energy (eV) | quantum yield |
| Host | Chemical | −5.5 | −2.8 | −3.0 | 0.3 |
| | Formula 37 | | | | |
| | Bebq₂ | | | | |
| | Chemical | −5.9 | −2.8 | −3.1 | 0.3 |
| | Formula 38 | | | | |
| | Bepbo₂ | | | | |
| | Chemical | −5.8 | −2.8 | −3.1 | 0.2 |
| | Formula 39 | | | | |
| | Bepbt₂ | | | | |
| | Chemical | −5.6 | −2.6 | −2.9 | 0.3 |
| | Formula 40 | | | | |
| | Bepp₂ | | | | |
| | Chemical | −5.5 | −3.1 | −3.2 | 0.2 |
| | Formula 41 | | | | |
| | Liqin | | | | |
| | CBP | −5.8 | −2.5 | −3.0 | — |
| Dopant | Ir(ppy)3 | −5.4 | −3.0 | −3.0 | |
| | Ir(phq)₂acac | −5.2 | −3.2 | −3.2 | |
| | Ir(piq)₃ | −5.0 | −3.0 | −3.1 | |

### Example 1 and Comparative Example 1

### Preparation of Green Organic Light Emitting Diode (OLED)

### Example 1

A Corning 15 Ω/cm² (1200 Å) ITO glass substrate was cut into a size of 50 mm×50 mm×0.7 mm, subjected to ultrasonic wave cleaning in each of isopropyl alcohol and pure water for 5 minutes, and subjected to the UV and ozone cleaning for 30 minutes.

N,N′-di(1-naphthyl)-N,N′-diphenylbenzidine (NPD) was evaporated on the surface of the substrate, to provide a hole transport layer (HTL) in a thickness of 40 nm.

On the surface of the hole transport layer (HTL), a host material (Bepp₂) represented by the above Formula 40 and tris(2-phenylpyridine)iridium (Ir(ppy)₃) dopant were deposited at the same time to provide an emission layer, and a LiF/Al cathode was deposited thereon to provide a green organic light emitting diode (OLED). The thickness and material used for each layer are described in the following Table 2.

### Comparative Example 1

A green organic light emitting diode (OLED) was prepared in accordance with the same procedure as in Example 1, except that a CBP (4,4′-N,N′-dicarbazole-biphenyl) host and an Ir(ppy)₃ dopant were used as the emission layer material, and a BAlq hole blocking layer, an Alq3 electron transport layer, and a LiF electron injection layer were further coated sequentially on the emission layer.

TABLE 2

| | Hole | | Hole | Electron | |
|---|---|---|---|---|---|
| | transport | | blocking | transport | |
| | layer (HTL) | Emission layer | layer | layer (ETL) | Cathode |
| Example 1 | NPD | Bepp₂: Ir(ppy)₃ | — | — | LiF |
| | 40 nm | 8 wt % | | | (1 nm)/Al |
| | | 50 nm | | | 100 nm |
| Comparative | NPD | CBP: Ir(ppy)₃ | BAlq | Alq3 | LiF |
| Example 1 | 40 nm | 8 wt % | (5 nm) | 30 nm | (1 nm)/Al |
| | | 30 nm | | | 100 nm |

Turn-on voltage, driving voltage, luminous efficiency, maximum efficiency, and color coordinate of the green organic light emitting diodes according to Example 1 and Comparative Example 1 were measured, and the results are shown in the following Table 3.

TABLE 3

| | | | Luminous efficiency | | | | |
|---|---|---|---|---|---|---|---|
| | | | (at 1000 cd/m²) | | Maximum efficiency | | |
| | Turn-on voltage | Driving voltage | current | electric power | current | electric power | CIE |
| | (V, at 1 cd/m²) | (V, at 1000 cd/m²) | (cd/A) | (lm/W) | (cd/A) | (lm/W) | (x, y) |
| Example 1 | 2.5 | 4.9 | 19.18 | 12.05 | 19.95 | 18.85 | 0.32, 0.59 |
| Comparative | 5.3 | 9.6 | 19.92 | 6.52 | 22.36 | 10.95 | 0.31, 0.60 |
| Example 1 | | | | | | | |

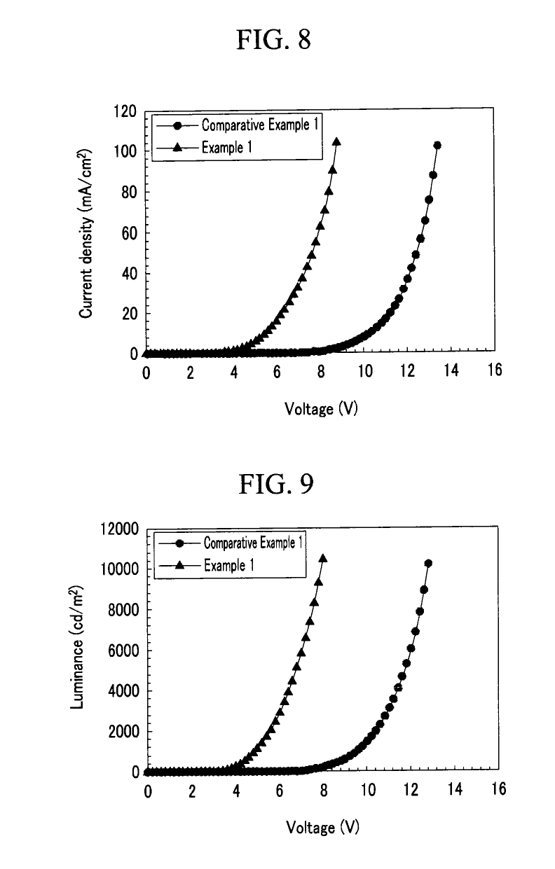

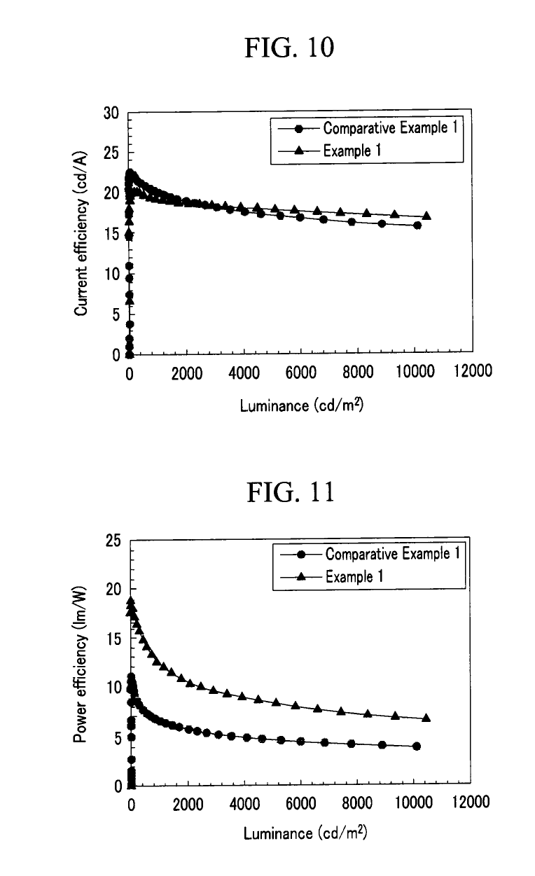

The I-V characteristic and V-L characteristic of each green organic diode according to Example 1 and Comparative Example 1 are shown in FIGS. 8 and 9, respectively; luminous efficiency (current efficiency) and electric power efficiency are shown in FIGS. 10 and 11, respectively.

From the results of Table 3 and FIGS. 8 to 11, it is confirmed that the organic light emitting diode (OLED) according to Example 1 was able to achieve a low voltage driving and high efficiency characteristic compared to those of the organic light emitting diode according to Comparative Example 1 of the multi-structure using CBP. This is because the CBP host according to Comparative Example 1 does not allow easy implant of the charge from a hole transport layer (HTL) or a hole blocking layer to an emission layer due to the large bandgap, while the host according to Example 1 can accomplish easy injection of the charge due to the small bandgap.

Since the host used in Example 1 has a difference between the reduction potential or oxidation potential of the host and the reduction potential or oxidation potential of the dopant of less than 0.5 eV, the energy transfer is easier than that of CBP of more than 0.5 eV, and the LUMO excited state of these hosts is placed in a similar level to that of triplet excited state of the Ir(ppy)₃ dopant to minimize the charge trap.

Furthermore, in Example 1, it is possible to provide the green organic light emitting diode (OLED) having a simple structure that has no hole blocking layer and no electron transport layer (ETL) because it has low driving voltage and high efficiency characteristics.

### Examples 2-11 and Comparative Example 2

### Preparation of Red Organic Light Emitting Diode (OLED)

### Example 2

A Corning 15 Ω/cm² (1200 Å) ITO glass substrate was cut into a size of 50 mm×50 mm×0.7 mm, subjected to ultrasonic wave cleaning in each of isopropyl alcohol and pure water for 5 minutes, and subjected to UV and ozone cleaning for 30 minutes.

N,N′-di(1-naphthyl)-N,N′-diphenylbenzidine (NPD) was evaporated on the surface of substrate at a thickness of 40 nm to provide a hole transport layer (HTL).

A Bepq₂ host material represented by the above Formula 37 and a tris(1-phenylisoquinoline)iridium (Ir(piq)₃) dopant were deposited on the surface of hole transport layer (HTL) at the same time to provide an emission layer, and a LiF/Al cathode was deposited thereon to provide a red organic light emitting diode (OLED). The thickness and material used for each layer are shown in the following Table 4.

### Example 3

A Corning 15 Ω/cm² (1200 Å) ITO glass substrate was cut into a size of 50 mm×50 mm×0.7 mm, subjected to ultrasonic wave cleaning in each of isopropyl alcohol and pure water for 5 minutes, and subjected to UV and ozone cleaning for 30 minutes.

N,N′-di(1-naphthyl)-N,N′-diphenylbenzidine (NPD) was evaporated on the surface of the substrate at a thickness of 40 nm to provide a hole transport layer (HTL).

A Bepq₂ host material represented by the above Formula 37 and a tris(1-phenylisoquinoline)iridium (Ir(piq)₃) dopant were deposited on the surface of the hole transport layer at the same time to provide an emission layer.

The compound represented by Chemical Formula 8 was evaporated on the surface of the emission layer at a thickness of 5 nm to provide an electron transport layer. On the electron transport layer, a LiF/Al cathode was deposited to provide a red organic light emitting diode. The thickness and material used for each layer are shown in the following Table 4.

### Example 4

A Corning 15 Ω/cm² (1200 Å) ITO glass substrate was cut into a size of 50 mm×50 mm×0.7 mm, subjected to ultrasonic wave cleaning in isopropyl alcohol and pure water for 5 minutes, and subjected to UV and ozone cleaning for 30 minutes.

PEDOT:PSS was spin-coated on the surface of the substrate to provide a hole injection layer (HIL) at a thickness of 40 nm.

N,N′-di(1-naphthyl)-N,N′-diphenylbenzidine (NPD) was evaporated on the surface of hole injection layer (HIL) at a thickness of 40 nm to provide a hole transport layer (HTL).

A Bepq₂ host material represented by the above Formula 37 and a tris(1-phenylisoquinoline)iridium (Ir(piq)₃) dopant were deposited on the surface of the hole transport layer at the same time to provide an emission layer.

The compound represented by Chemical Formula 8 was evaporated on the surface of the emission layer at a thickness of 5 nm to provide an electron transport layer. A LiF/Al cathode was deposited on the electron transport layer to provide a red organic light emitting diode. The thickness and material used for each layer are shown in the following Table 4.

### Example 5

A Corning 15 Ω/cm² (1200 Å) ITO glass substrate was cut into a size of 50 mm×50 mm×0.7 mm, subjected to ultrasonic wave cleaning in each of isopropyl alcohol and pure water for 5 minutes, and subjected to UV and ozone cleaning for 30 minutes.

N,N′-di(1-naphthyl)-N,N′-diphenylbenzidine (NPD) was evaporated on the surface of the substrate at a thickness of 40 nm to provide a hole transport layer.

The host material (Bepp₂) represented by the above Formula 40 and a tris(1-phenylisoquinoline)iridium (Ir(piq)₃) dopant were deposited on the surface of the hole transport layer (HTL) at the same time to provide an emission layer, and a LiF electron injection layer (EIL) and an Al cathode were further deposited thereon to provide a red organic light emitting diode. The thickness and material used for each layer are shown in the following Table 4.

### Example 6

A red organic light emitting diode (OLED) was prepared in accordance with the same procedure as in Example 5, except that a Bebpt₂ host represented by Chemical Formula 39 and an Ir(piq)₃ dopant were used as the emission layer material in the amounts shown in the following Table 4.

### Example 7

A red organic light emitting diode was prepared in accordance with the same procedure as in Example 5, except that a Bepbo₂ host represented by Chemical Formula 38 and an Ir(piq)₃ dopant were used as the emission layer material in amounts shown in the following Table 4.

### Examples 8-11

A red organic light emitting diode was prepared in accordance with the same procedure as in Example 5, except that a Bebq₂ host represented by Chemical Formula 37 and an Ir(piq)₃ dopant were used as the emission layer material in amounts shown in the following Table 4.

TABLE 4

| | Hole | Hole | | Hole | Electron | |
|---|---|---|---|---|---|---|
| | injection | transport | Emission | blocking | transport | |
| | layer | layer | layer | layer | layer | Cathode |
| Example 2 | — | NPD | Bepq₂: Ir(piq)₃ | — | — | LiF (5 nm)/ |
| | | 40 nm | 10 wt % | | | Al 100 nm |
| | | | 50 nm | | | |
| Example 3 | — | NPD | Bepq₂: Ir(piq)₃ | — | — | LiF (5 nm)/ |
| | | 40 nm | 10 wt % | | | Al 100 nm |
| | | | 50 nm | | | |
| Example 4 | PEDOT: PSS | NPD | Bepq₂: Ir(piq)₃ | — | chemical | LiF (5 nm)/ |
| | 40 nm | 40 nm | 10 wt % | | formula 8 | Al 100 nm |
| | | | 50 nm | | (5 nm) | (1 nm) |
| Example 5 | — | NPD | Bepp₂: Ir(piq)₃ | — | — | LiF (1 nm)/ |
| | | 40 nm | 8 wt % | | | Al 100 nm |
| | | | 50 nm | | | |
| Example 6 | — | NPD | Bebpt₂: Ir(piq)₃ | — | — | LiF (1 nm)/ |
| | | 40 nm | 8 wt % | | | Al 100 nm |
| | | | 50 nm | | | |
| Example 7 | — | NPD | Bepbo₂: Ir(piq)₃ | — | — | LiF (1 nm)/ |
| | | 40 nm | 8 wt % | | | Al 100 nm |
| | | | 50 nm | | | |
| Example 8 | — | NPD | Bebq₂: Ir(piq)₃ | — | — | LiF (1 nm)/ |
| | | 40 nm | 10 wt % | | | Al 100 nm |
| | | | 50 nm | | | |
| Example 9 | — | NPD | Bebq₂: Ir(piq)₃ | — | — | LiF (1 nm)/ |
| | | 40 nm | 8 wt % | | | Al 100 nm |
| | | | 50 nm | | | |
| Example 10 | — | NPD | Bebq₂: Ir(piq)₃ | — | — | LiF (1 nm)/ |
| | | 40 nm | 6 wt % | | | Al 100 nm |
| | | | 50 nm | | | |
| Example 11 | — | NPD | Bebq₂: Ir(piq)₃ | — | — | LiF (1 nm)/ |
| | | 40 nm | 4 wt % | | | Al 100 nm |
| | | | 50 nm | | | |
| Comparative | — | NPD | CBP: Ir(piq)₃ | BAlq | Alq3 | LiF (1 nm)/ |
| Example 2 | | 40 nm | 8 wt % | (5 nm) | 20 nm | Al 100 nm |
| | | | 30 nm | | | |

Each red light emitting diode according to Examples 2-11 and Comparative Example 2 was measured for turn-on voltage, driving voltage, luminous efficiency, maximum luminous efficiency, and color coordinate, and the results are shown in the following Table 5.

TABLE 5

| | | | Luminous efficiency | | | | |
|---|---|---|---|---|---|---|---|
| | | | (at 1000 cd/m²) | | Maximum efficiency | | |
| | Turn-on voltage | Driving voltage | Current | Electric power | Current | Electric power | CIE |
| | (V, at 1 cd/m²) | (V, at 1000 cd/m²) | (cd/A) | (lm/W) | (cd/A) | (lm/W) | (x, y) |
| Example 2 | 2.2 | 4.6 | 9.1 | 6.2 | 9.84 | 10.24 | 0.67, 0.33 |
| Example 3 | 2.4 | 5.8 | 7.7 | 4.1 | 8.57 | 11.22 | 0.66, 0.33 |
| Example 4 | 2.2 | 4.8 | 9.7 | 6.4 | 10.65 | 12.78 | 0.66, 0.33 |
| Example 5 | 2.4 | 4.5 | 9.67 | 6.90 | 11.07 | 14.50 | 0.67, 0.32 |
| Example 6 | 2.5 | 4.9 | 4.49 | 2.93 | 4.75 | 4.33 | 0.66, 0.33 |
| Example 7 | 2.6 | 6.4 | 5.49 | 2.75 | 9.33 | 6.98 | 0.66, 0.33 |
| Example 8 | 2.1 | 3.5 | 6.78 | 5.92 | 7.38 | 8.10 | 0.67, 0.32 |
| Example 9 | 2.1 | 3.5 | 7.18 | 6.26 | 7.82 | 10.40 | 0.67, 0.32 |
| Example 10 | 2.1 | 3.5 | 7.65 | 6.68 | 8.37 | 10.67 | 0.67, 0.32 |
| Example 11 | 2.1 | 3.5 | 8.41 | 7.34 | 9.38 | 11.72 | 0.67, 0.32 |
| Comp. Ex. 2 | 3.5 | 8.8 | 5.06 | 1.81 | 8.67 | 4.00 | 0.60, 0.31 |

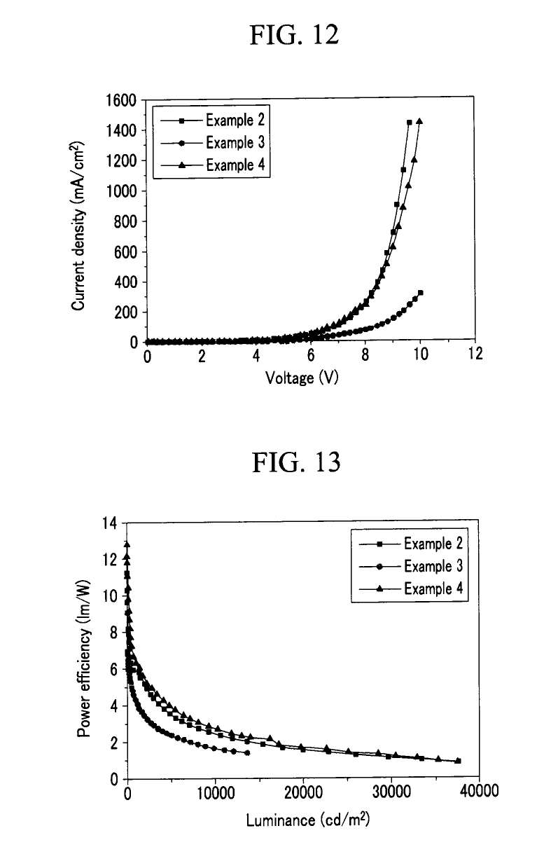

Each red organic light emitting diode according to Examples 2-4 was measured to determine the I-V characteristic and the electric power efficiency, and the result of measuring the I-V characteristic is shown in FIG. 12 and the result of measuring the electric power efficiency is shown in FIG. 13.

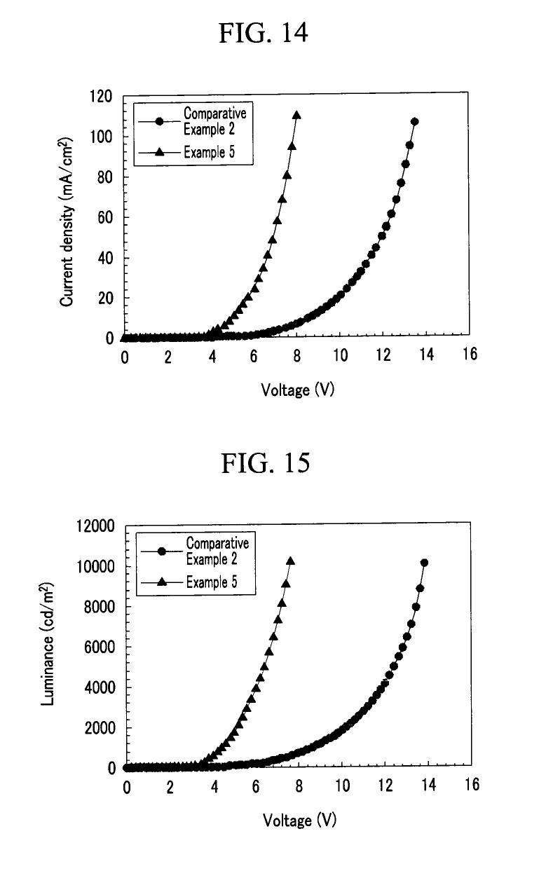

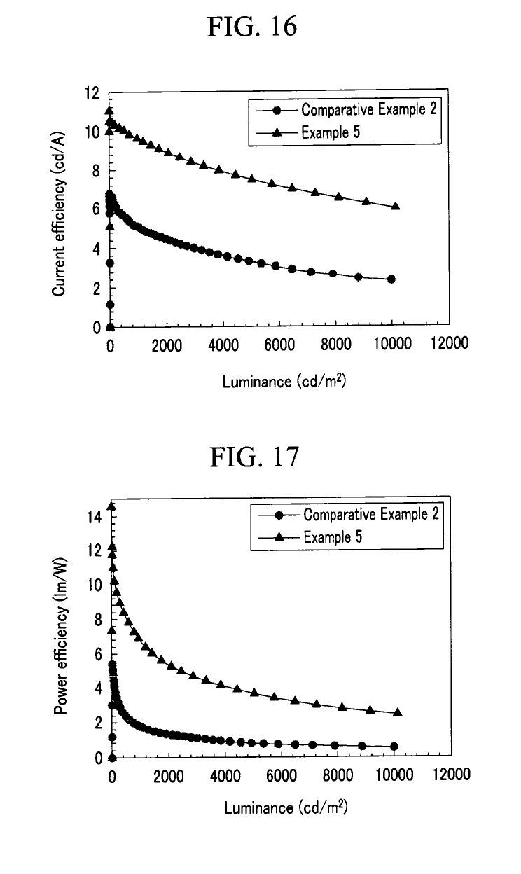

Each red organic light emitting diode (OLED) according to Example 5 and Comparative Example 2 was measured for I-V characteristic and V-L characteristic, and the results are shown in FIGS. 14 and 15, respectively. Luminous efficiency (current efficiency) and electric power efficiency thereof are shown in FIGS. 16 and 17, respectively.

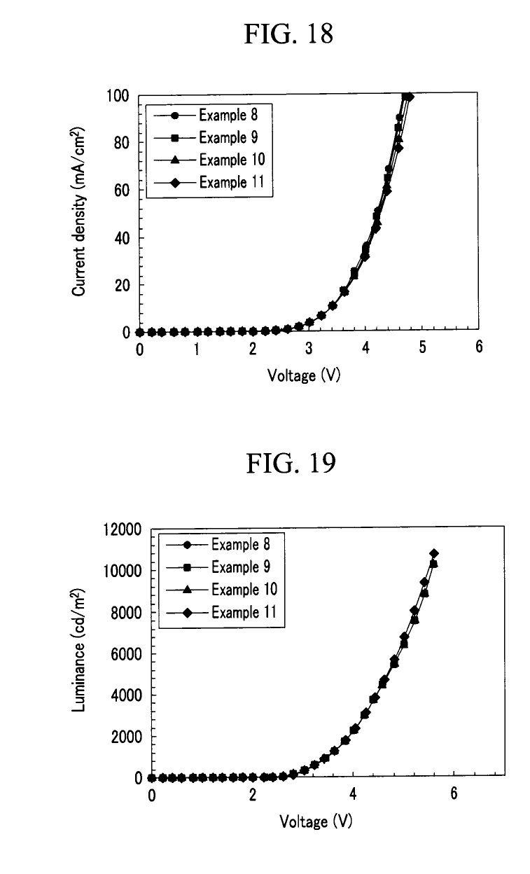

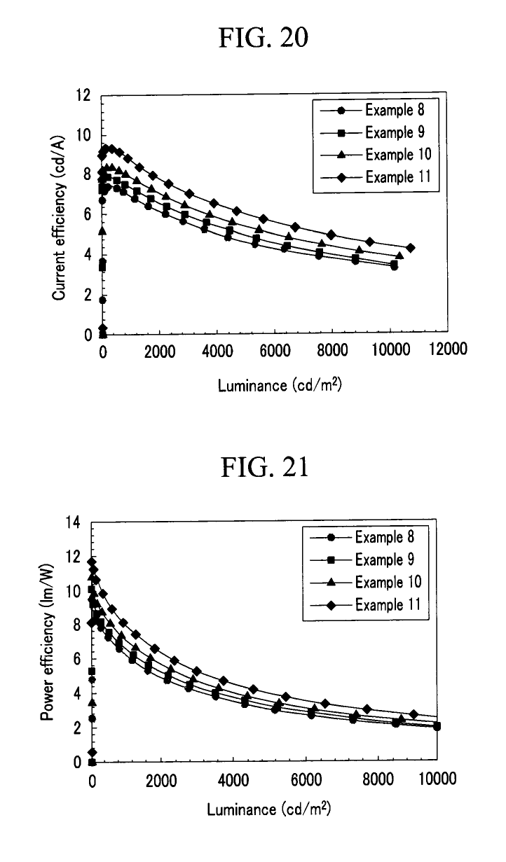

The I-V characteristic and the V-L characteristic of each red organic light emitting diodes according to Examples 8-11 are shown in FIGS. 18 and 19, respectively, and luminous efficiency (current efficiency) and electric power efficiency thereof are shown in FIGS. 20 and 21, respectively.

From the results of Table 5 and FIGS. 12 to 17, it is confirmed that the organic light emitting diodes (OLED) according to Examples 2-11 could accomplish the low voltage driving and the high efficiency characteristic compared to those of the organic light emitting diode according to Comparative Example 2 having a multi-structure using CBP. This is because the CBP host according to Comparative Example 2 does not allow easy injection of the charge from a hole transport layer (HTL) or a hole blocking layer to an emission layer due to the large bandgap, while the hosts according to Examples 2-11 could accomplish easy injection of the charge due to the small bandgap.

Since the hosts used in Examples 2-11 had differences between the reduction potential or the oxidation potential of the host and the reduction potential or the oxidation potential of the dopant of less than 0.5 eV, the energy transfer is easier than that of CBP of more than 0.5 eV, and the LUMO excited state of these hosts was similar to the level of the triplet excited state of the Ir(pig)₃ dopants so as to minimize the charge trap.

Furthermore, in Examples 2-11, it was possible to provide a red organic light emitting diode having a simple structure with no hole blocking layer and no electron transport layer because they had low driving voltage and high efficient characteristics.

In addition, it is confirmed that there were no problems such as lift-up exciplex or electroplex that often occur at the interface between the organic layers by considering the constant value of color coordinate of organic light emitting diode. Thereby, it is possible to improve the luminous efficiency, interface adhesiveness, and color purity.

### Examples 12-15

### Organic Light Emitting Diode (OLED) Characteristic Depending upon Doping Concentration

### Examples 12-15

A Corning 15 Ω/cm² (1200 Å) ITO glass substrate was cut into a size of 50 mm×50 mm×0.7 mm, subjected to the ultrasonic wave cleaning in each of isopropyl alcohol and pure water for 5 minutes, and subjected to UV and ozone cleaning for 30 minutes.

N,N′-di(1-naphthyl)-N,N′-diphenylbenzidine (NPD) was evaporated on the surface of the substrate at a thickness of 40 nm to provide a hole transport layer.

The host material (Bepq₂) represented by Chemical Formula 33 and a bis(2-phenylquinoline)iridium acetylacetonate (Ir(phq)_{2acac}) dopant were deposited at the same time to provide an emission layer. Then, a LiF electron injection layer and an Al cathode were deposited to provide a red organic light emitting diode. The thickness and material used for each layer are shown in the following Table 6.

TABLE 6
Structure of Red Phosphorescent Organic Light Emitting
Diode (OLED)

| | Hole transport | | |
|---|---|---|---|
| | layer (HTL) | Emission layer | Cathode |
| Example 12 | NPD 40 nm | Bepq₂:Ir(phq)_{2acac} | LiF (1 nm)/ |
| | | 0.5 wt % 50 nm | Al 100 nm |
| Example 13 | NPD 40 nm | Bepq₂:Ir(phq)_{2acac} | LiF (1 nm)/ |
| | | 1 wt % 50 nm | Al 100 nm |
| Example 14 | NPD 40 nm | Bepq₂:Ir(phq)_{2acac} | LiF (1 nm)/ |
| | | 1.5 wt % 50 nm | Al 100 nm |
| Example 15 | NPD 40 nm | Bepq₂:Ir(phq)_{2acac} | LiF (1 nm)/ |
| | | 2 wt % 50 nm | Al 100 nm |

Each red organic light emitting diode according to Examples 12-15 was measured for turn-on voltage, driving voltage, luminous efficiency, maximum luminous efficiency, and color coordinate, and the results are shown in the following Table 7.

| | | | Luminous efficiency | | | | |
|---|---|---|---|---|---|---|---|
| | | | (at 1000 cd/m²) | | Maximum efficiency | | |
| | Turn-on voltage | Driving voltage | Current | Electric power | Current | Electric power | CIE |
| | (V, at 1 cd/m²) | (V, at 1000 cd/m²) | (cd/A) | (lm/W) | (cd/A) | (lm/W) | (x, y) |
| Example 12 | 2.1 | 3.7 | 20.96 | 18.29 | 21.25 | 24.62 | 0.61, 0.38 |
| Example 13 | 2.1 | 3.7 | 20.53 | 23.14 | 26.53 | 29.58 | 0.62, 0.37 |
| Example 14 | 2.1 | 3.6 | 22.61 | 19.73 | 23.46 | 29.94 | 0.62, 0.37 |
| Example 15 | 2.1 | 3.6 | 21.45 | 18.72 | 22.73 | 27.94 | 0.62, 0.37 |

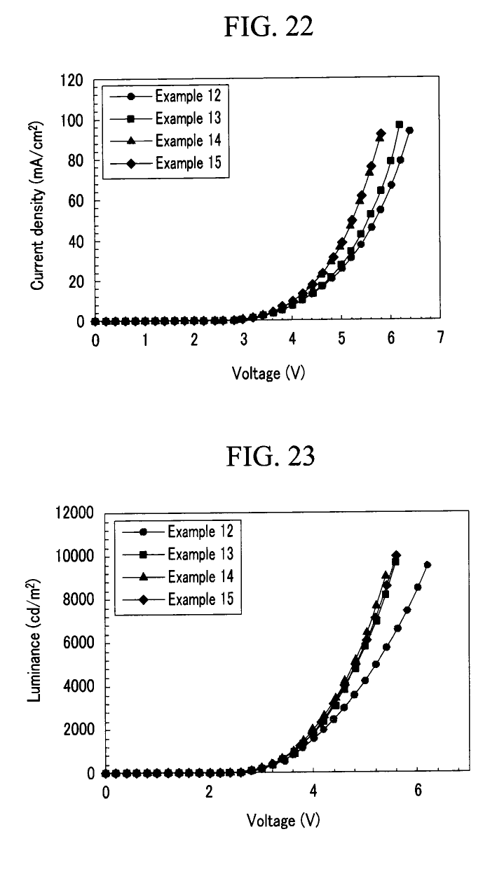

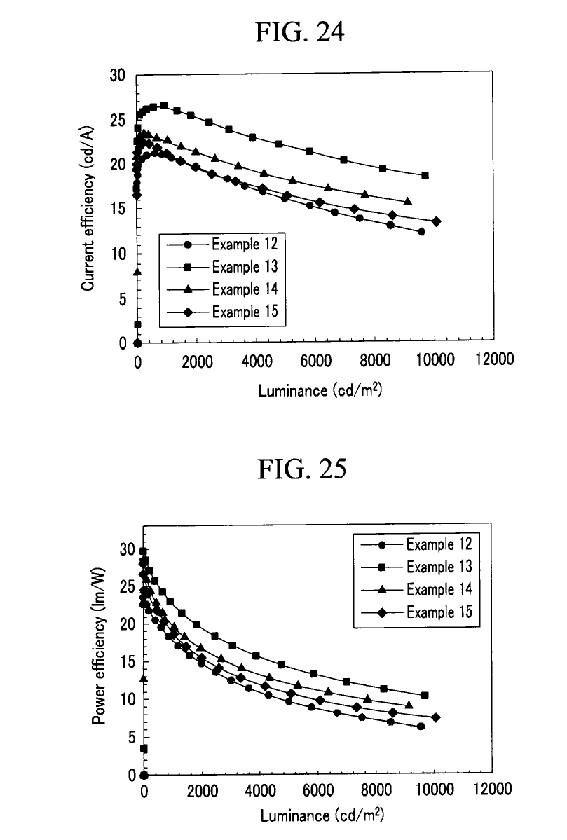

The I-V characteristic and V-L characteristic of each red organic light emitting diode according to Examples 12-15 are shown in FIGS. 22 and 23, respectively, and luminous efficiency (current efficiency) and electric power efficiency thereof are shown in FIGS. 24 and 25, respectively.

As shown in Table 7 and FIGS. 22 to 25, in Examples 12-15, since the difference between the reduction potential or oxidation potential of the Bepq₂ host and the reduction potential or oxidation potential of the dopant is less than 0.5 eV, the energy transport is fast. In addition, since the triplet excited state of the host is present near to the triplet excited state of the dopant, the energy transfer is facilitated to improve the luminous efficiency at a low doping concentration. As the host is a phosphor material, the energy transfer from the singlet excited state of the host to the triplet excited state of the dopant becomes easier.

### Example 16

### Preparation of White Organic Light Emitting Diode

A Corning 15 Ω/cm² (1200 Å) ITO glass substrate was cut into a size of 50 mm×50 mm×0.7 mm, subjected to ultrasonic wave cleaning in each of isopropyl alcohol and pure water for 5 minutes, and subjected to UV and ozone cleaning for 30 minutes.

N,N′-di(1-naphthyl)-N,N′-diphenylbenzidine (NPD) was evaporated on the surface of the substrate at a thickness of 40 nm to provide a hole transport layer (HTL).

The host material (Bebq₂) represented by Chemical Formula 33 was applied at a thickness of 40 nm to form a first emission layer; then the host material represented by Chemical Formula 33 and an Ir(phq)_{2acac} dopant (dopant amount: 8 wt %) were deposited at the same time to provide a second emission layer having a thickness of 10 nm. A LiF electron injection layer (EIL) and an Al cathode were deposited thereon to provide a white organic light emitting diode (OLED).

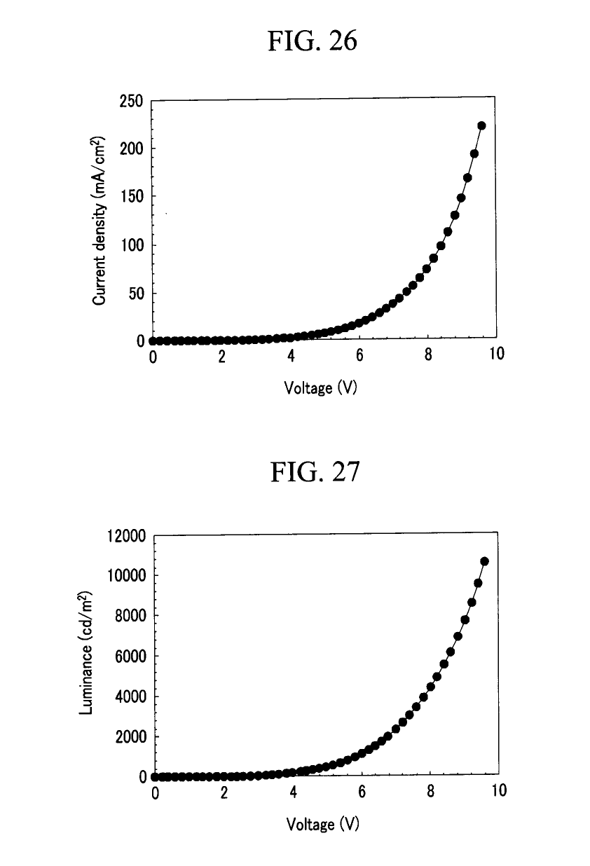

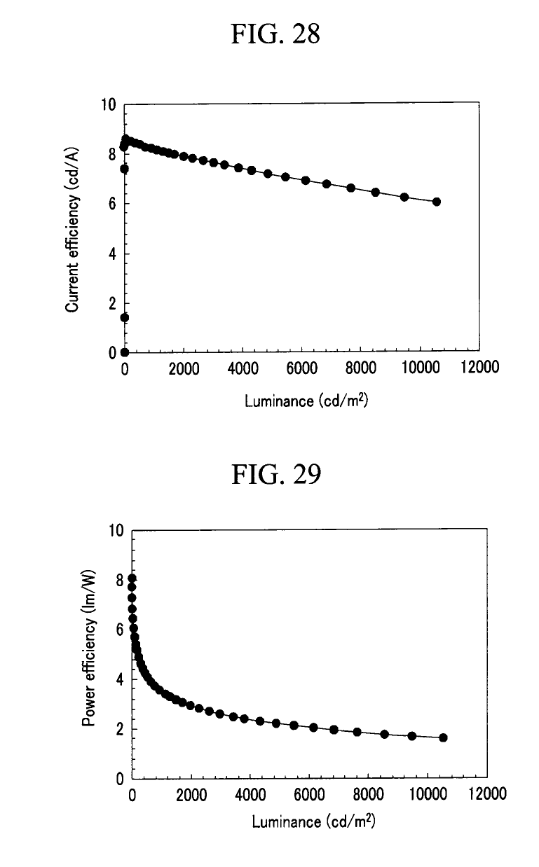

The I-V characteristic and V-L characteristic of the white organic light emitting diode according to Example 16 are shown in FIGS. 26 and 27, respectively. Furthermore, the luminous efficiency (current efficiency) and the power efficiency of the white organic light emitting diode of Example 16 are shown in FIGS. 28 and 29, respectively.

From the results of FIGS. 26 to 29, it is confirmed that white light emitting diodes according to the present invention could accomplish the low driving voltage and the high efficiency characteristics. In other words, it is confirmed that it was possible to provide a white organic light emitting diode having a simple structure with no hole blocking layer and no electron transport layer.

Since the hosts have a small difference between the reduction potential or oxidation potential of the host and the reduction potential or oxidation potential of the dopant of less than 0.5 eV in the present invention, the energy transfer is easier than that of CBP having a difference of more than 0.5 eV. In addition, due to the fast electron transfer capacity of the host, it made the charge balance, so excitons are formed. Since the energy difference between the energy potential of the singlet excited state of the new host and the energy potential of the triplet excited state of the dopant is small, and it is a fluorescent host, it was possible to accomplish the fast energy transfer and the excellent device characteristics.

### INDUSTRIAL APPLICABILITY

According to the present invention, the organic photoelectric device further improves the capacity of injecting electrons because there are no hole blocking layer and electron transport layer, as well as improves the energy transfer efficiency from the singlet excited state of the host to the triplet excited state of the phosphorescent dopant. Thereby, it provides the phosphorescent organic photoelectric device characteristics such as high efficiency and low driving voltage. Furthermore, it is possible to reduce the fabrication cost by simplifying the structure. Accordingly, the organic photoelectric device according to the present invention can be applied to a back-light for a thin-film transistor liquid crystal display (TFT-LCD), a light-emitting element of an active-matrix organic light-emitting display, a lighting device, and so on.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. An organic photoelectric device comprising:
a substrate;
an anode disposed on the substrate;
a hole transport layer (HTL) disposed on the anode;
an emission layer disposed on the hole transport layer (HTL); and
a cathode disposed on the emission layer,
wherein the emission layer comprises a host and a phosphorescent dopant, and a difference between a reduction potential or an oxidation potential of the host and a reduction potential or an oxidation potential of the phosphorescent dopant is less than 0.5 eV.

2. The organic photoelectric device of claim 1, wherein the difference between a reduction potential or an oxidation potential of the host and a reduction potential or an oxidation potential of the phosphorescent dopant is 0.4 eV or less.

3. The organic photoelectric device of claim 1, wherein the difference between a reduction potential or an oxidation potential of the host and a reduction potential or an oxidation potential of the phosphorescent dopant is 0.2 eV or less.

4. The organic photoelectric device of claim 1, wherein the host has an energy difference between a singlet excited state and a triplet excited state of 0.3 eV or less.

5. The organic photoelectric device of claim 1, wherein the host is an organic metal complex compound represented by the following Formula 1 or 2:
ML [Chemical Formula 1]
ML₁L₂ [Chemical Formula 2]
wherein, in the above formulae, M is selected from the group consisting of Li, Na, Mg, K, Ca, Al, Be, Zn, Pt, Ni, Pd, and Mn, and L, L₁, and L₂ are independently a ligand.

6. The organic photoelectric device of claim 5, wherein L₁ and L₂ of the above Formula 2 are different.

7. The organic photoelectric device of claim 1, wherein the host is an organic metal complex compound represented by the following Formula 3: 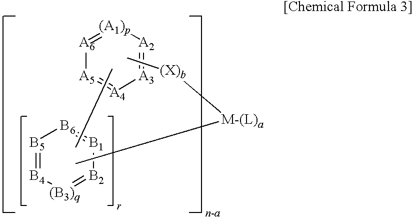
wherein, in the above formula,
A₁ to A₆ are independently CR₁R₂ (where R₁ and R₂ are independently selected from the group consisting of hydrogen, a halogen, a nitrile, a cyano, a nitro, an amide, a carbonyl, an ester, a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₁ and R₂ of A₁ to A₆ is linked to at least one non-adjacent R₁ and R₂ of A₁ to A₆ to form a fused ring);
B₁ to B₆ are independently CR₃R₄ or NR₅ (where R₃, R₄, and R₅ are independently hydrogen, a halogen, a nitrile, a cyano, a nitro, an amide, a carbonyl, an ester; a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₃, R₄, and R₅ of B₁ to B₆ is linked to at least one non-adjacent R₃, R₄, and R₅ of B₁ to B₆ to form a fused ring); or
at least one of R₁ and R₂ of A₁ to A₆ is linked to at least one of R₃, R₄, and R₅ of B₁ to B₆ to form a fused ring;
p, q, and r are independently integers of 0 or 1;
L is selected from the group consisting of OR₆ and OSiR₇R₈ (where R₆, R₇, and R₈ are independently an aryl, an alkyl-substituted aryl, an arylamine, a cycloalkyl, and a heterocycle);
M is selected from the group consisting of Li, Na, Mg, K, Ca, Al, Be, Zn, Pt, Ni, Pd, and Mn;
X is oxygen or sulfur;
n is a metal valence; and
a and b are independently 0 or 1.

8. The organic photoelectric device of claim 7, wherein the host is selected from the group consisting of organic metal complex compounds represented by the following Formulae 5 to 36 and mixtures thereof: 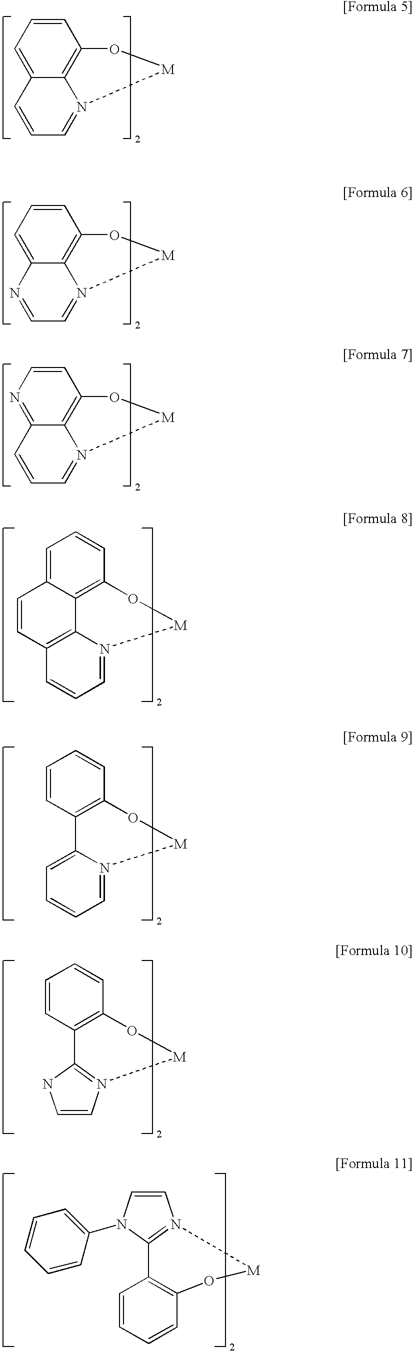 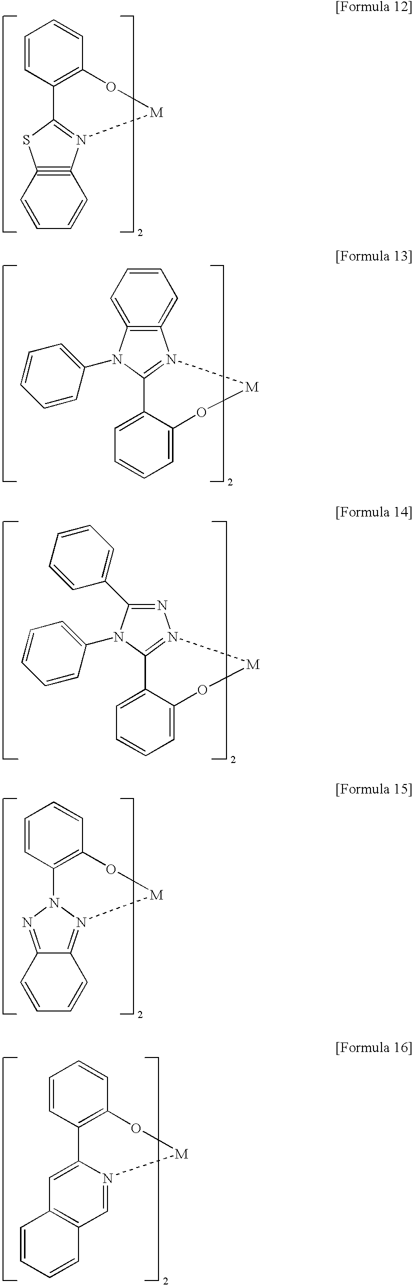 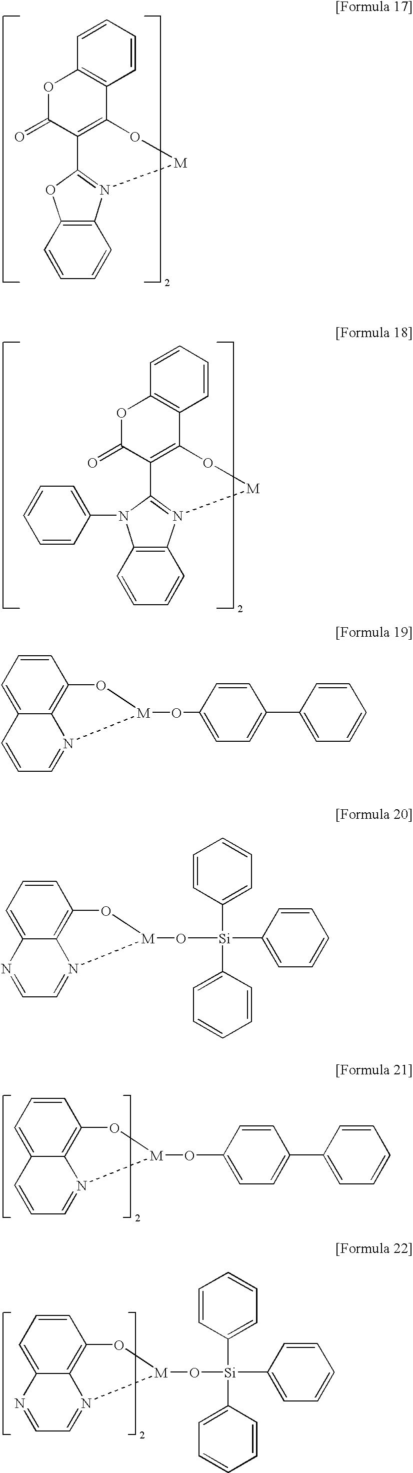 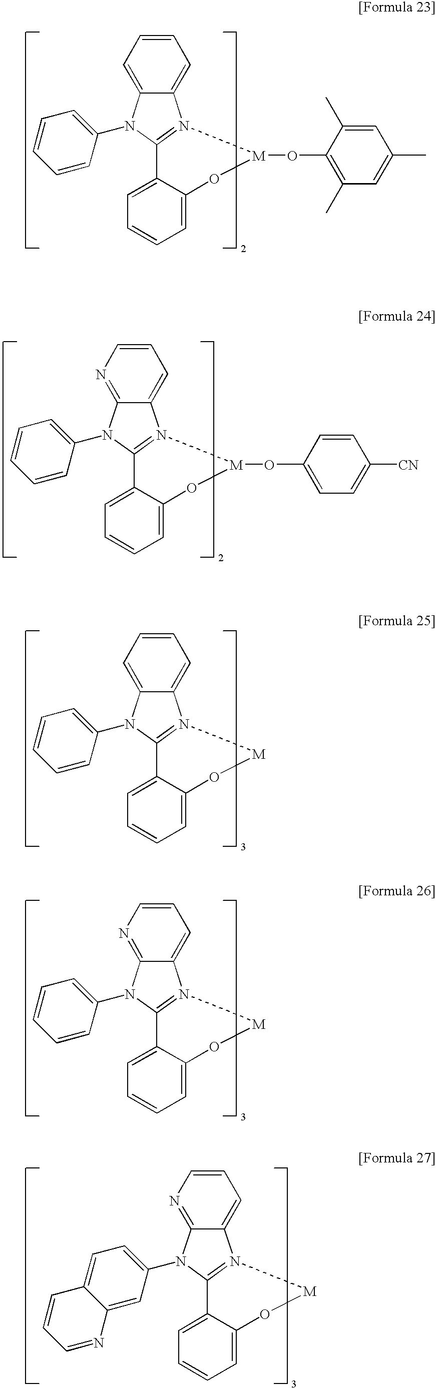 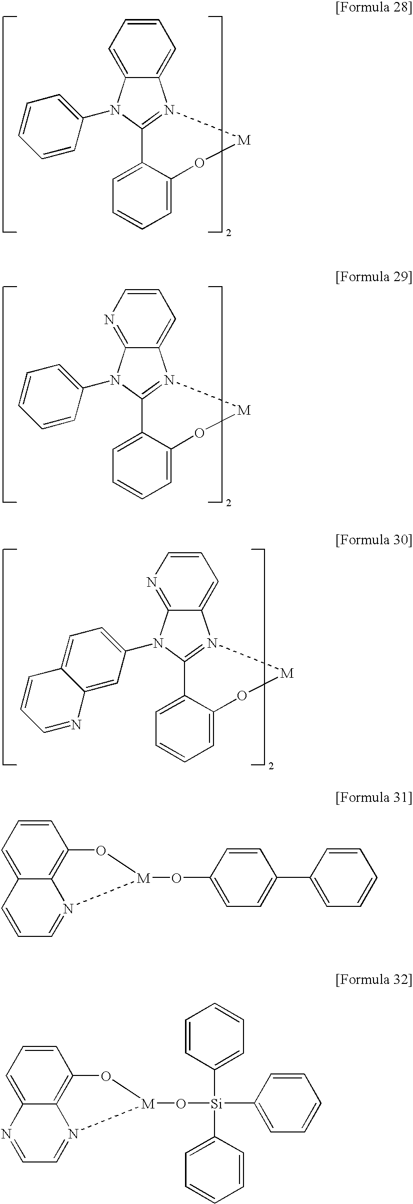 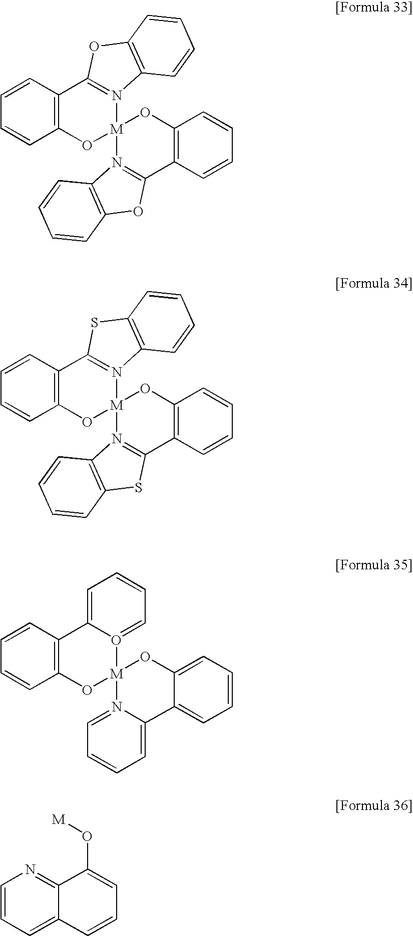
wherein, in the above formula, M is determined according to valance, and is selected from the group consisting of Li, Na, Mg, K, Ca, Al, Be, Zn, Pt, Ni, Pd, and Mn.

9. The organic photoelectric device of claim 1, wherein the host has a fluorescent quantum yield of 0.01 or more.

10. The organic photoelectric device of claim 9, wherein the host has a fluorescent quantum yield of 0.1 or more.

11. The organic photoelectric device of claim 1, wherein the phosphorescent dopant is included in an amount of 0.5 to 20 wt % based on the total weight of the light emitting material (host+dopant).

12. The organic photoelectric device of claim 11, wherein the phosphorescent dopant is included in an amount of 0.5 to 5 wt % based on the total weight of the light emitting material (host+dopant).

13. The organic photoelectric device of claim 12, wherein the phosphorescent dopant is included in an amount of 0.5 to 5 wt % based on the total weight of the light emitting material (host+dopant).

14. The organic photoelectric device of claim 13, wherein the phosphorescent dopant is included in an amount of 0.5 to 1 wt % based on the total weight of the light emitting material (host+dopant).

15. The organic photoelectric device of claim 1, wherein the host has electron mobility of 10⁻⁶ cm²/Vs or more.

16. The organic photoelectric device of claim 1, wherein the device further comprises a hole blocking layer or an electron transport layer (ETL) disposed on the emission layer.

17. The organic photoelectric device of claim 1, wherein the device further comprises a hole blocking layer disposed on the emission layer, and an electron transport layer (ETL) disposed on the hole blocking layer.

18. The organic photoelectric device of claim 17, wherein the hole blocking layer or electron transport layer (ETL) is formed of the host of the emission layer.

19. The organic photoelectric device of claim 1, wherein the phosphorescent dopant comprises at least one selected from the group consisting of Ir, Pt, Tb, Eu, Os, Ti, Zr, Hf, and Tm.

20. An organic photoelectric device comprising:
a substrate;
an anode disposed on the substrate;
a hole transport layer (HTL) disposed on the anode;
an emission layer disposed on the hole transport layer (HTL); and
a cathode disposed on the emission layer,
wherein the emission layer comprises a host and a phosphorescent dopant, and a difference between a reduction potential or an oxidation potential of the host and a reduction potential or an oxidation potential of the phosphorescent dopant is 0.4 eV or less, and
the phosphorescent dopant is included in an amount of 3 wt % or less based on the total weight of the light emitting material (host+dopant).

21. The organic photoelectric device of claim 20, wherein the phosphorescent dopant is included in an amount of 0.5 to 1 wt % based on the total weight of the light emitting material (host+dopant).

22. The organic photoelectric device of claim 20, wherein the host has a fluorescent quantum yield of 0.01 or more.

23. The organic photoelectric device of claim 22, wherein the host has a fluorescent quantum yield of 0.1 or more.

24. The organic photoelectric device of claim 20, wherein the host is an organic metal complex compound represented by the following Formula 3: 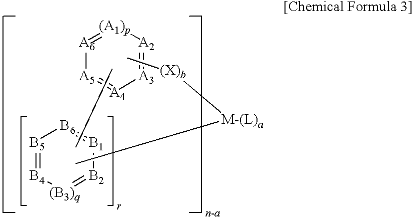
wherein, in the above formula,
A₁ to A₆ are independently CR₁R₂ (where R₁ and R₂ are independently selected from the group consisting of hydrogen, a halogen, a nitrile, a cyano, a nitro, an amide, a carbonyl, an ester, a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₁ and R₂ of A₁ to A₆ is linked to at least one non-adjacent R₁ and R₂ of A₁ to A₆ to form a fused ring);
B₁ to B₆ are independently CR₃R₄ or NR₅ (where R₃, R₄, and R₅ are independently hydrogen, a halogen, a nitrile, a cyano, a nitro, an amide, a carbonyl, an ester; a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₃, R₄, and R₅ of B₁ to B₆ is linked to at least one non-adjacent R₃, R₄, and R₅ of B₁ to B₆ to form a fused ring); or
at least one of R₁ and R₂ of A₁ to A₆ is linked to at least one of R₃, R₄, and R₅ of B₁ to B₆ to form a fused ring;
p, q, and r are independently integers of 0 or 1;
L is selected from the group consisting of OR₆ and OSiR₇R₈ (where R₆, R₇, and R₈ are independently an aryl, an alkyl-substituted aryl, an arylamine, a cycloalkyl, and a heterocycle);
M is selected from the group consisting of Li, Na, Mg, K, Ca, Al, Be, Zn, Pt, Ni, Pd, and Mn;
X is oxygen or sulfur;
n is a metal valence; and
a and b are independently 0 or 1.

25. An organic metal complex compound, wherein the compound is used for an emission layer material of an organic photoelectric device and is represented by the following Formula 3: 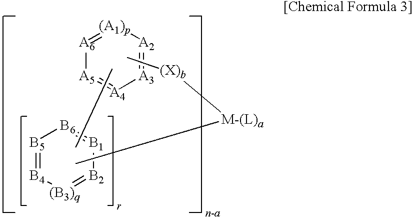
wherein, in the above formula
A₁ to A₆ are independently CR₁R₂ (where R₁ and R₂ are independently selected from the group consisting of hydrogen, a halogen, a nitrile, a cyano, a nitro, an amide, a carbonyl, an ester, a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₁ and R₂ of A₁ to A₆ is linked to at least one non-adjacent R₁ and R₂ of A₁ to A₆ to form a fused ring);
B₁ to B₆ are independently CR₃R₄ or NR₅ (where R₃, R₄, and R₅ are independently hydrogen, a halogen, a nitrile, a cyano, a nitro, an amide, a carbonyl, an ester; a substituted or unsubstituted alkyl, a substituted or unsubstituted alkoxy, a substituted or unsubstituted alkenyl, a substituted or unsubstituted aryl, a substituted or unsubstituted arylamine, a substituted or unsubstituted hetero arylamine, a substituted or unsubstituted heterocycle, a substituted or unsubstituted amino, and a substituted or unsubstituted cycloalkyl, or at least one of R₃, R₄, and R₅ of B₁ to B₆ is linked to at least one non-adjacent R₃, R₄, and R₅ of B₁ to B₆ to form a fused ring); or
at least one of R₁ and R₂ of A₁ to A₆ is linked to at least one of R₃, R₄, and R₅ of B₁ to B₆ to form a fused ring;
p, q, and r are independently integers of 0 or 1;
L is selected from the group consisting of OR₆ and OSiR₇R₈ (where R₆, R₇, and R₈ are independently an aryl, an alkyl-substituted aryl, an arylamine, a cycloalkyl, and a heterocycle);
M is selected from the group consisting of Li, Na, Mg, K, Ca, Be, Zn, Pt, Ni, Pd, and Mn;
X is oxygen or sulfur;
n is a metal valence; and
a and b are independently 0 or 1.

26. The organic metal complex compound of claim 25, wherein the host is selected from the group consisting of organic metal complex compounds represented by the following Formulae 5 to 36 and mixtures thereof: 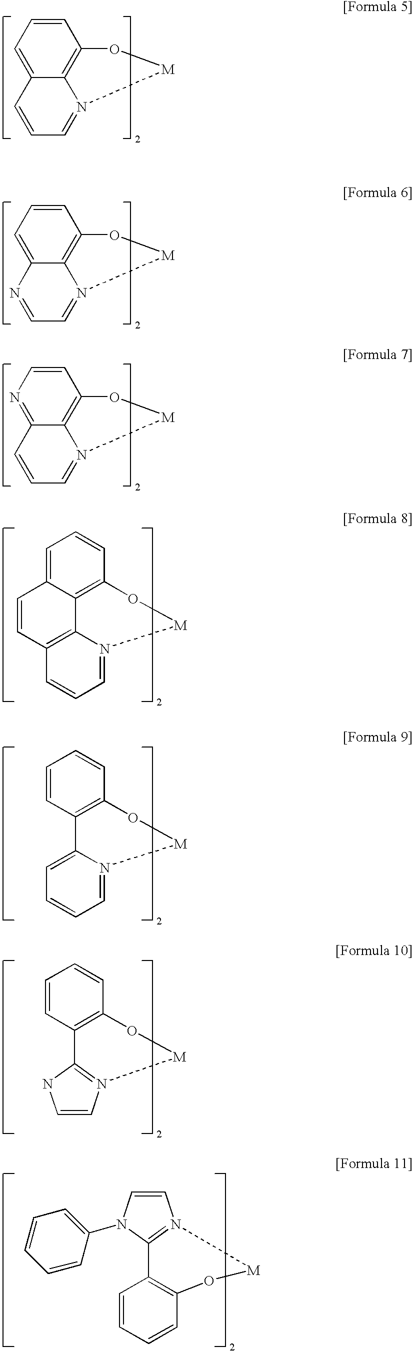 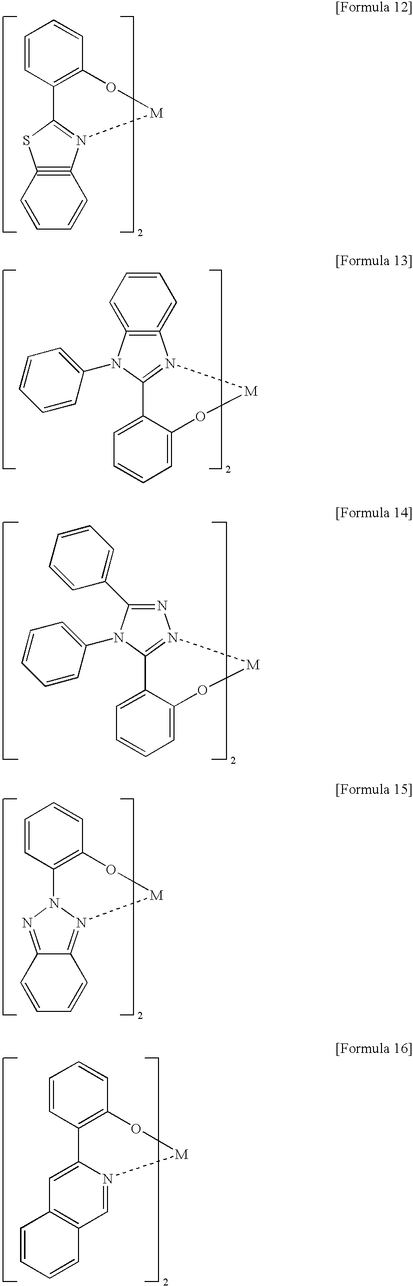 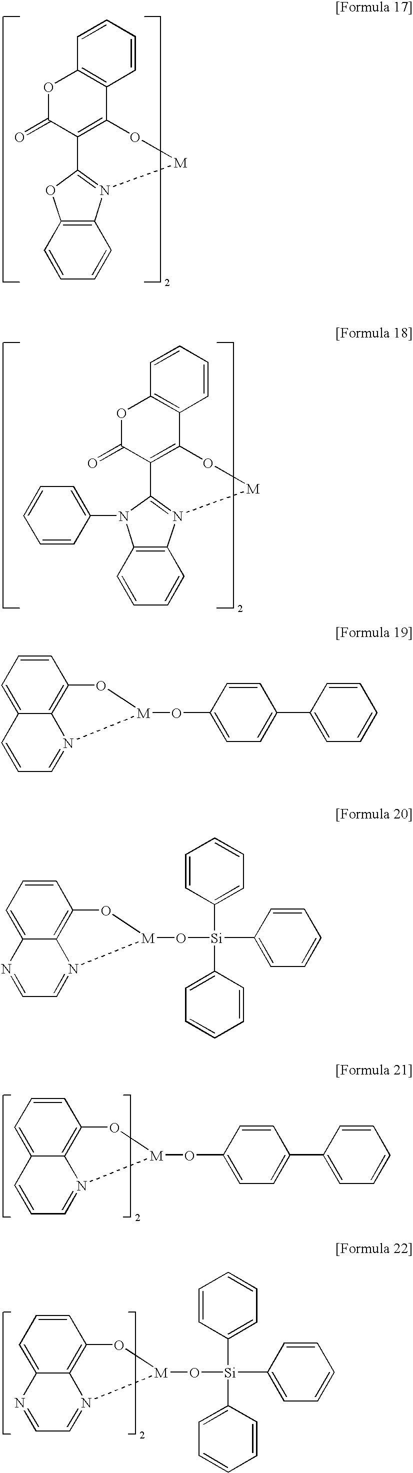 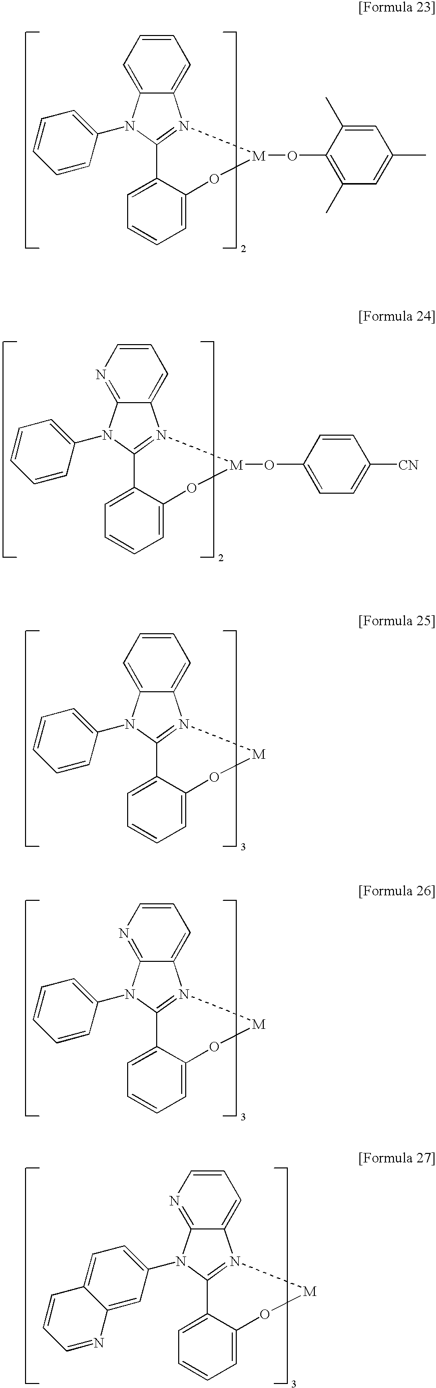 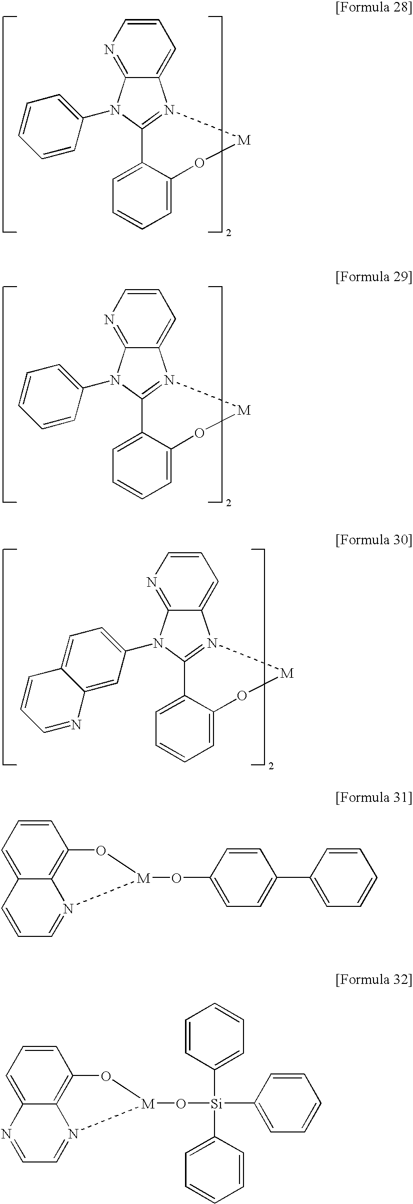 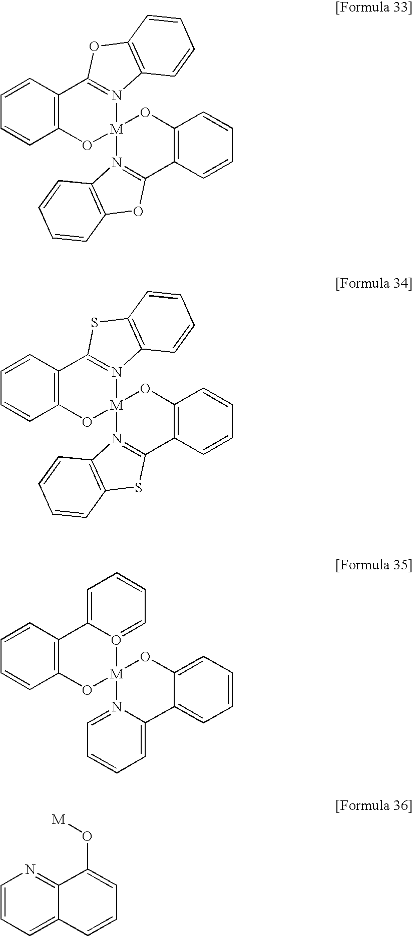
wherein, in the above formulae, M is determined according to valance, and is selected from the group consisting of Li, Na, Mg, K, Ca, Al, Be, Zn, Pt, Ni, Pd, and Mn.
